(19) United States
(12) Patent Application Publication
(10) Pub. No.: US 2026/0013193 A1
(43) Pub. Date: Jan. 8, 2026

(54) SEMICONDUCTOR DEVICE WITH SPACER AND METHOD FOR FABRICATING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/765,102

(22) Filed: Jul. 5, 2024

(51) Int. Cl. H01L 29/66; H01L 21/762; H01L 21/764; H01L 23/528; H01L 23/532

(52) U.S. Cl. CPC H10D 64/018; H01L 21/76224; H01L 21/764; H01L 23/528; H01L 23/5283; H01L 23/53257; H01L 23/5329

(57) ABSTRACT

The present application discloses a semiconductor device and a method for fabricating the semiconductor device. The semiconductor device includes a substrate; a buried conductive layer including a bottom portion positioned in the substrate, and a top portion positioned in the substrate and on the bottom portion; an isolation layer positioned in the substrate; an air gap structure positioned in the isolation layer; and an in-recess spacer positioned in the substrate, surrounding the bottom portion and covered by the top portion. A top surface of the top portion and a top surface of the substrate are substantially coplanar. A bottom surface of the in-recess spacer and a bottom surface of the bottom portion are substantially coplanar. A sidewall of the in-recess spacer and a sidewall of the top portion are substantially coplanar.

### TECHNICAL FIELD

The present disclosure relates to a semiconductor device and a method for fabricating the semiconductor device, and more particularly, to a semiconductor device with a spacer and a method for fabricating the semiconductor device with the spacer.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a buried conductive layer including a bottom portion positioned in the substrate and a top portion positioned in the substrate and on the bottom portion; an isolation layer positioned in the substrate; an air gap structure positioned in the isolation layer; and an in-recess spacer positioned in the substrate, surrounding the bottom portion, and covered by the top portion. A top surface of the top portion and a top surface of the substrate are substantially coplanar. A bottom surface of the in-recess spacer and a bottom surface of the bottom portion are substantially coplanar. A sidewall of the in-recess spacer and a sidewall of the top portion are substantially coplanar.

Another aspect of the present disclosure provides a semiconductor device including a substrate; a buried conductive layer including a bottom portion positioned in the substrate and a top portion positioned in the substrate and on the bottom portion; a shallow trench isolation (STI) structure positioned in the substrate; and an in-recess spacer positioned in the substrate, surrounding the bottom portion, and covered by the top portion. A top surface of the top portion and a top surface of the substrate are substantially coplanar. A bottom surface of the in-recess spacer and a bottom surface of the bottom portion are substantially coplanar. A sidewall of the in-recess spacer and a sidewall of the top portion are substantially coplanar.

Another aspect of the present disclosure provides a method for fabricating a semiconductor device including providing a substrate and forming an isolation layer in the substrate to define a plurality of active areas; forming an opening in the substrate; conformally forming a layer of spacer material in the opening; performing a spacer etching process to remove a portion of the spacer material and form an in-recess spacer in the opening; and forming a buried conductive layer in the opening and covering the in-recess spacer, wherein an air gap structure is formed in the isolation layer.

Another aspect of the present disclosure provides a method for fabricating a semiconductor device including providing a substrate and forming an isolation layer in the substrate to define a plurality of active areas; forming an opening in the substrate; conformally forming a layer of spacer material in the opening; performing a spacer etching process to remove a portion of the spacer material and form an in-recess spacer in the opening; and forming a buried conductive layer in the opening and covering the in-recess spacer, wherein a shallow trench isolation (STI) structure is formed in the substrate.

Due to the design of the semiconductor device of the present disclosure, an electrical field near the buried conductive layer may be reduced by employing the in-recess spacer. Therefore, a gate-induced drain leakage may be reduced due to the reduction of the electrical field. As a result, the performance of the semiconductor device is improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a semiconductor device in accordance with one embodiment of the present disclosure.

FIG. 2 is a schematic top-view diagram of an intermediate semiconductor device in accordance with one embodiment of the present disclosure.

FIG. 3 is a schematic cross-sectional diagram taken along lines A-A′ and B-B′ in FIG. 2.

FIG. 4 is a schematic top-view diagram of an intermediate semiconductor device in accordance with one embodiment of the present disclosure.

FIG. 5 is a schematic cross-sectional diagram taken along lines A-A′ and B-B′ in FIG. 4.

FIG. 6 is a schematic top-view diagram of an intermediate semiconductor device in accordance with one embodiment of the present disclosure.

FIG. 7 is a schematic cross-sectional diagram taken along lines A-A′ and B-B′ in FIG. 6.

FIG. 8 is a schematic top-view diagram of an intermediate semiconductor device in accordance with one embodiment of the present disclosure.

FIGS. 9 to 20 are schematic cross-sectional diagrams taken along lines A-A′ and B-B′ in FIG. 8 illustrating part of the flow for fabricating the semiconductor device in accordance with one embodiment of the present disclosure.

FIG. 21 is a schematic top-view diagram of an intermediate semiconductor device in accordance with one embodiment of the present disclosure;

FIG. 22 is a schematic cross-sectional diagram taken along lines A-A′ and B-B′ in FIG. 21.

FIG. 23 is a schematic top-view diagram of an intermediate semiconductor device in accordance with one embodiment of the present disclosure.

FIGS. 24 and 25 are schematic cross-sectional diagrams taken along lines A-A′ and B-B′ in FIG. 23 illustrating part of the flow for fabricating the semiconductor device in accordance with one embodiment of the present disclosure.

FIG. 26 is a schematic top-view diagram of an intermediate semiconductor device in accordance with one embodiment of the present disclosure.

FIGS. 27 and 28 are schematic cross-sectional diagrams taken along lines A-A′ and B-B′ in FIG. 26 illustrating part of the flow for fabricating the semiconductor device in accordance with one embodiment of the present disclosure.

FIG. 29 is a schematic top-view diagram of an intermediate semiconductor device in accordance with one embodiment of the present disclosure.

FIGS. 30 and 31 are schematic cross-sectional diagrams taken along lines A-A′ and B-B′ in FIG. 29 illustrating part of the flow for fabricating the semiconductor device in accordance with one embodiment of the present disclosure.

FIG. 32 is a schematic top-view diagram of an intermediate semiconductor device in accordance with another embodiment of the present disclosure.

FIG. 33 is a schematic cross-sectional diagram taken along lines A-A′ and B-B′ in FIG. 32.

FIG. 34 is a flowchart illustrating a method for fabricating a semiconductor device in accordance with one embodiment of the present disclosure.

FIGS. 35 and 36 are schematic cross-sectional diagrams taken along lines A-A′ and B-B′ in FIG. 29 illustrating part of the flow for fabricating the semiconductor device in accordance with one embodiment of the present disclosure.

FIG. 37 is a schematic cross-sectional diagram taken along lines A-A′ and B-B′ in FIG. 32.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the direction opposite to the direction of the arrow of the direction Z.

It should be noted that, in the description of the present disclosure, the terms “forming,” “formed” and “form” may mean and include any method of creating, building, patterning, implanting, or depositing an element, a dopant or a material. Examples of forming methods may include, but are not limited to, atomic layer deposition, chemical vapor deposition, physical vapor deposition, sputtering, co-sputtering, spin coating, diffusing, depositing, growing, implantation, photolithography, dry etching, and wet etching.

It should be noted that, in the description of the present disclosure, the functions or steps noted herein may occur in an order different from the order noted in the figures. For example, two figures shown in succession may in fact be executed substantially concurrently or may sometimes be executed in a reversed order, depending upon the functionalities or steps involved.

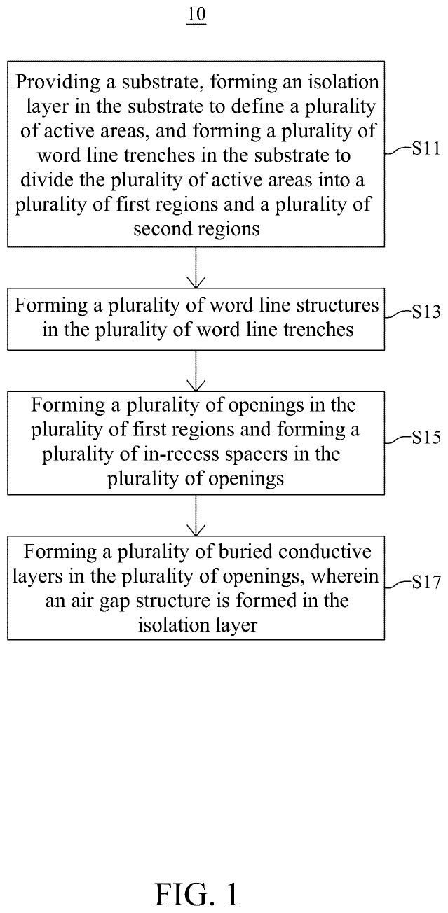

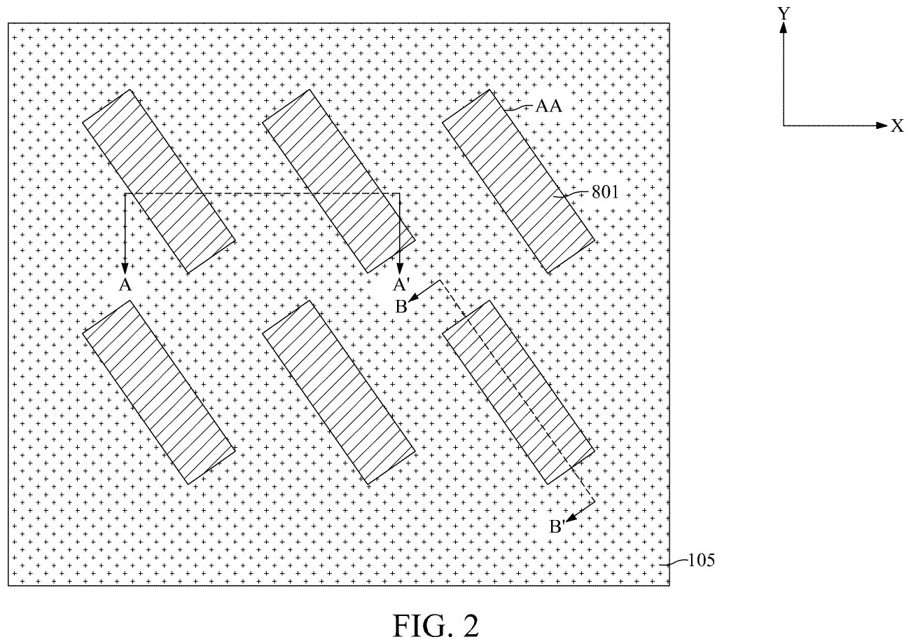

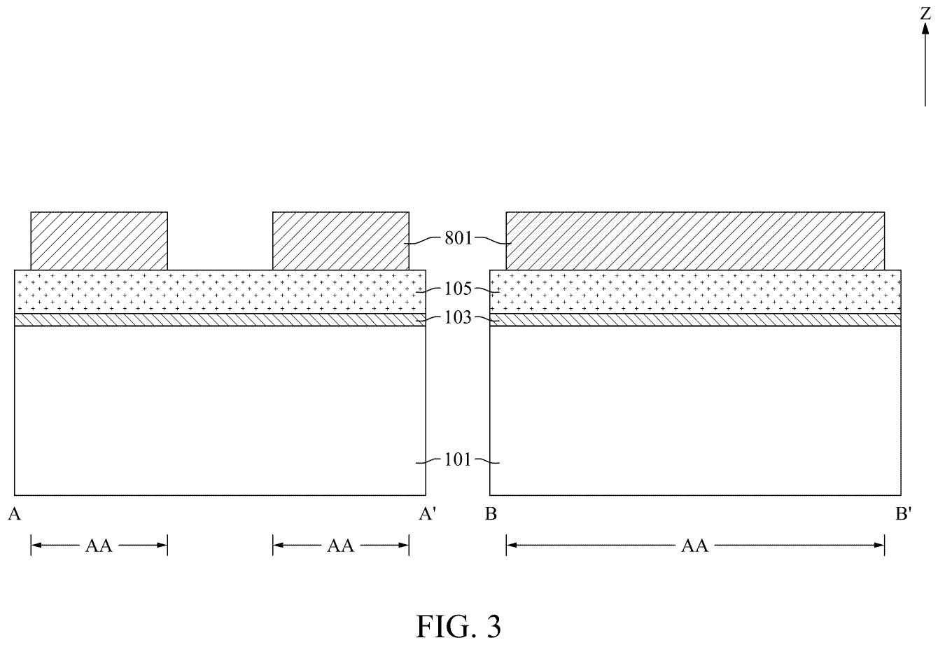

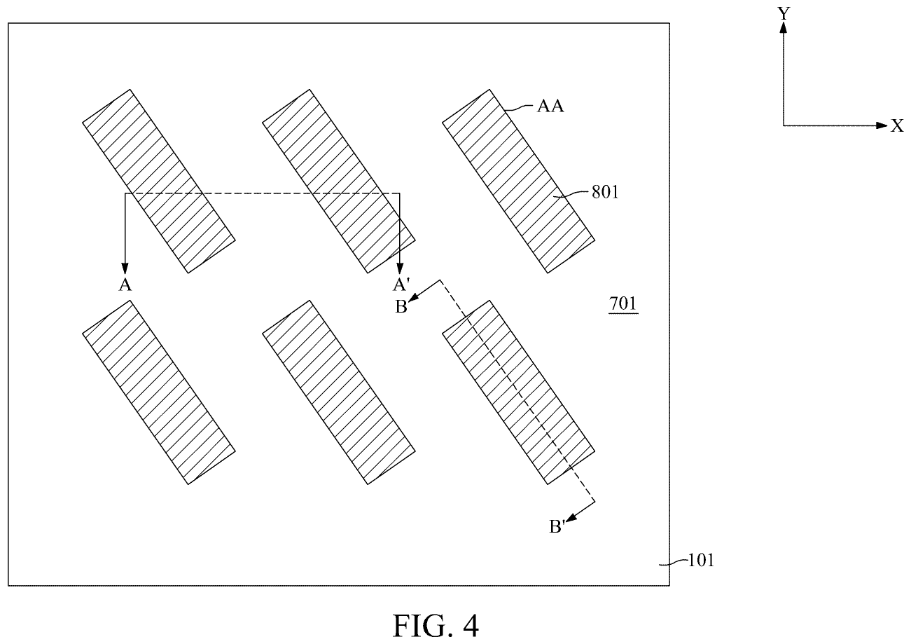

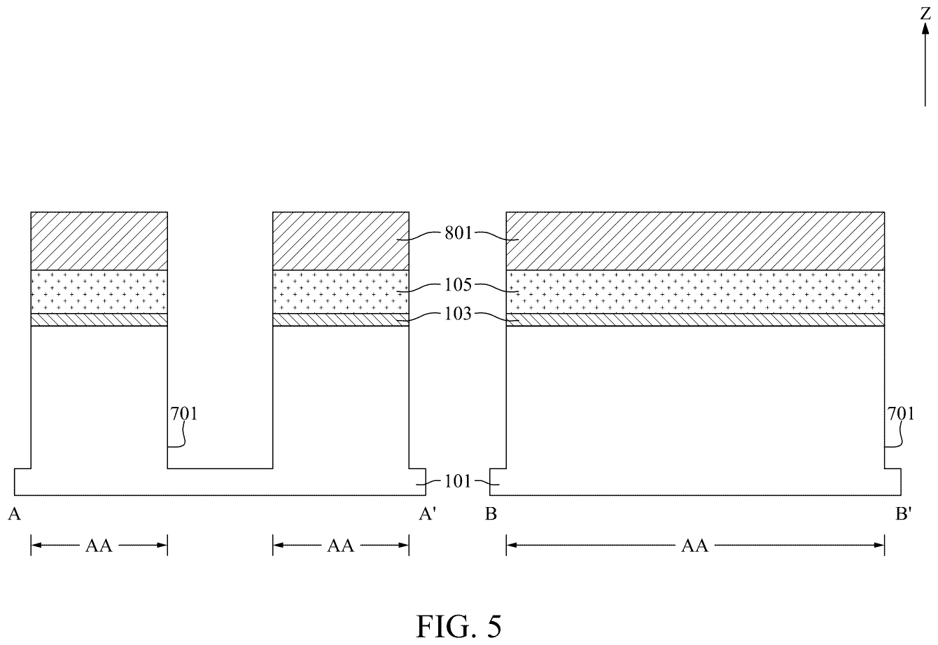

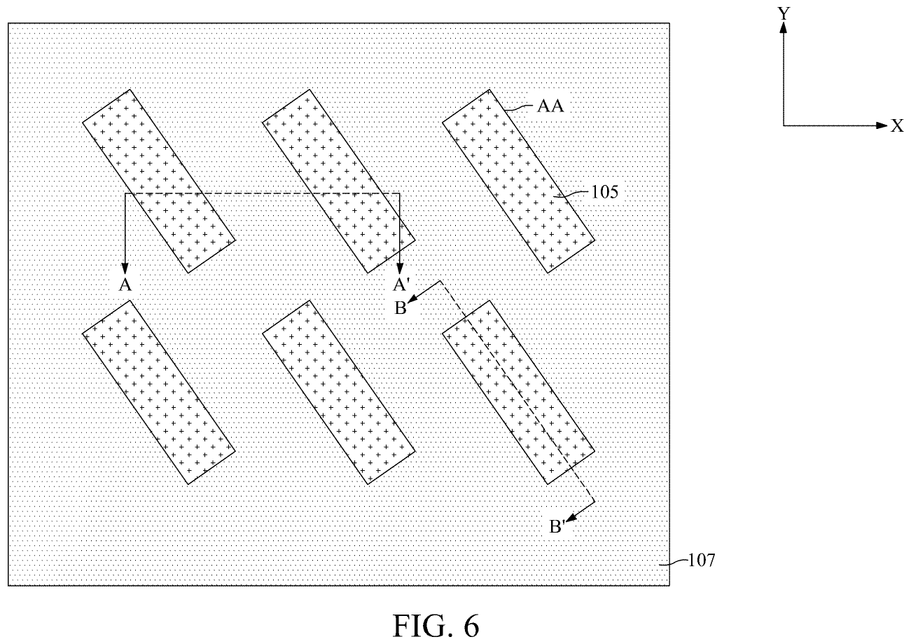

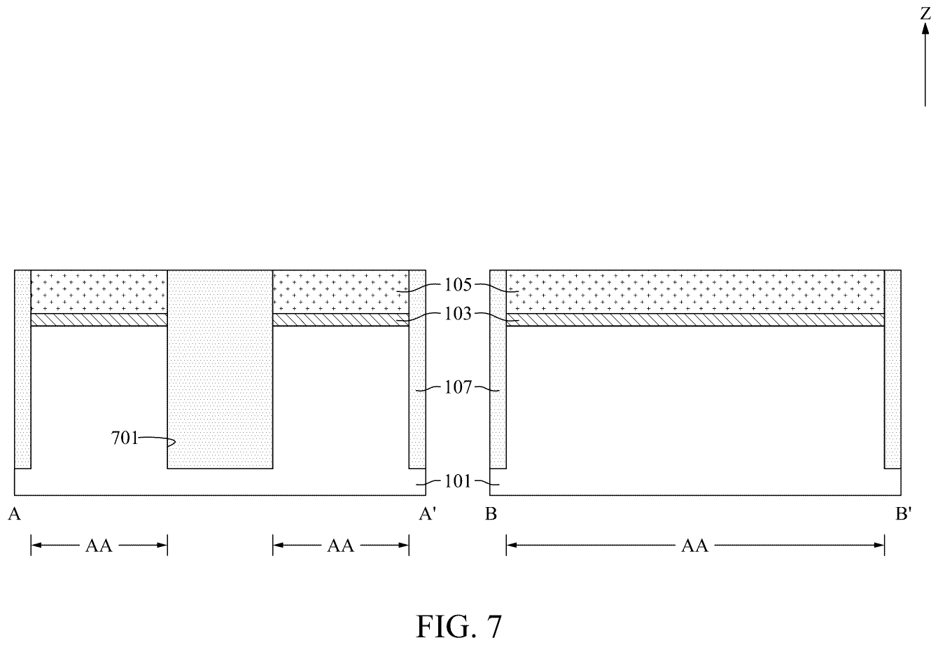

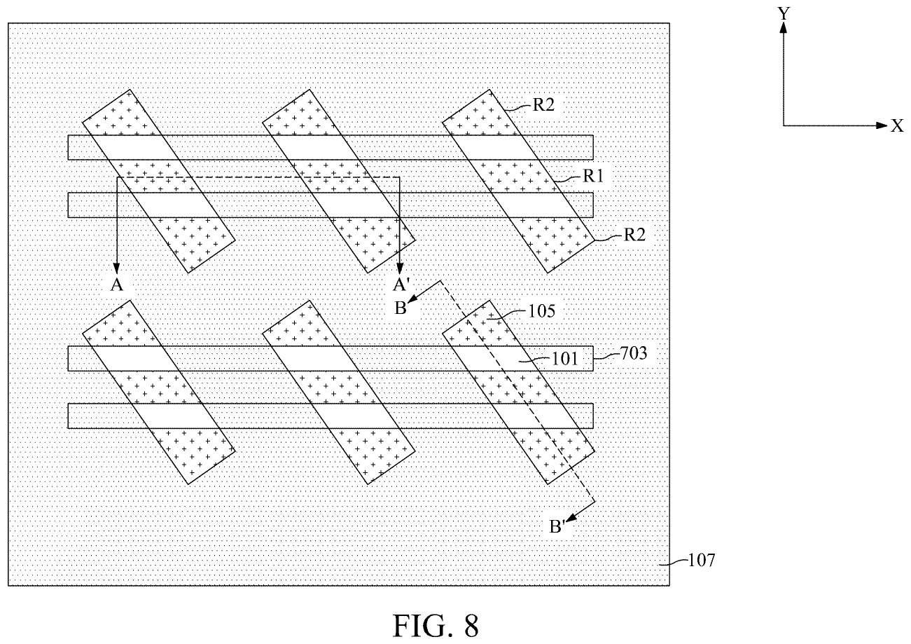

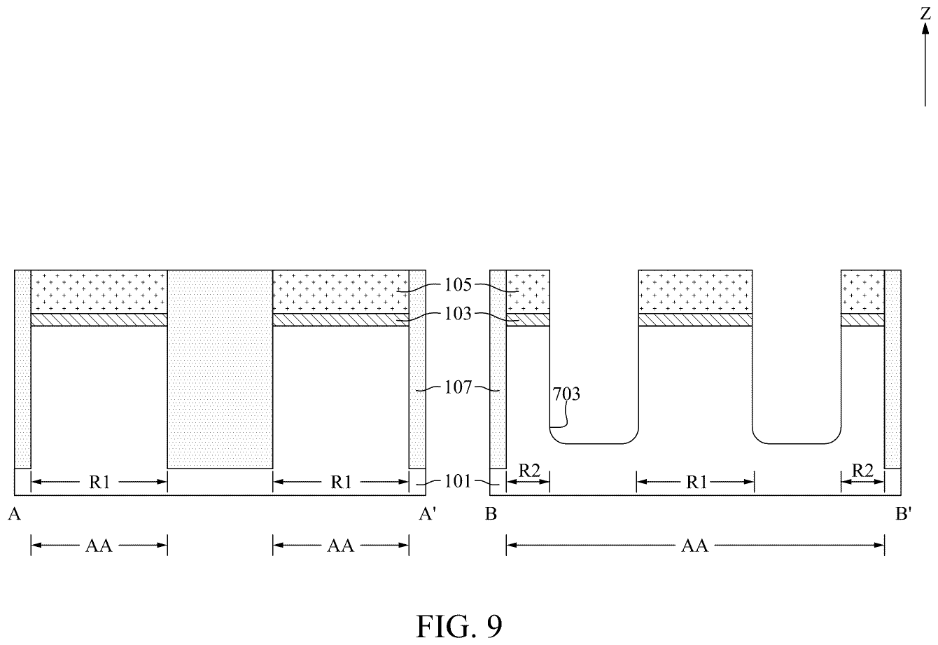

FIG. 1 is a flowchart illustrating a method 10 for fabricating a semiconductor device 1A in accordance with one embodiment of the present disclosure. FIG. 2 is a schematic top-view diagram of an intermediate semiconductor device in accordance with one embodiment of the present disclosure. FIG. 3 is a schematic cross-sectional diagram taken along lines A-A′ and B-B′ in FIG. 2. FIG. 4 is a schematic top-view diagram of an intermediate semiconductor device in accordance with one embodiment of the present disclosure. FIG. 5 is a schematic cross-sectional diagram taken along lines A-A′ and B-B′ in FIG. 4. FIG. 6 is a schematic top-view diagram of an intermediate semiconductor device in accordance with one embodiment of the present disclosure. FIG. 7 is a schematic cross-sectional diagram taken along lines A-A′ and B-B′ in FIG. 6. FIG. 8 is a schematic top-view diagram of an intermediate semiconductor device in accordance with one embodiment of the present disclosure. FIG. 9 is a schematic cross-sectional diagram taken along lines A-A′ and B-B′ in FIG. 8 illustrating part of the flow for fabricating the semiconductor device 1A in accordance with one embodiment of the present disclosure.

With reference to FIGS. 1 to 9, in step S11, a substrate 101 may be provided, an isolation layer 107 may be formed in the substrate 101 to define a plurality of active areas AA, and a plurality of word line trenches 703 may be formed in the substrate 101 to divide the plurality of active areas AA into a plurality of first regions R1 and a plurality of second regions R2.

With reference to FIGS. 2 and 3, in some embodiments, the substrate 101 may include a bulk semiconductor substrate that is composed of at least one semiconductor material. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate mentioned above. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and about 200 nm. The insulator layer may eliminate leakage current between adjacent elements in the substrate 101 and reduce parasitic capacitance associated with source/drains.

It should be noted that the term “about” modifying the quantity of an ingredient, component, or reactant of the present disclosure refers to variation in a numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

With reference to FIGS. 2 and 3, a series of deposition processes may be performed to deposit a pad oxide 103 and a pad nitride 105 on the substrate 101. A photolithography process may be performed to form a first mask layer 801 on the pad nitride 105 and to define the position of the isolation layer 107.

With reference to FIGS. 4 and 5, after the photolithography process, an etching process, such as an anisotropic dry etch process, may be performed to form a first trench 701 penetrating through the pad oxide 103 and the pad nitride 105, and extending into the substrate 101. After the formation of the first trench 701, the first mask layer 801 may be removed.

With reference to FIGS. 6 and 7, an insulating material such as silicon oxide, silicon nitride, silicon oxynitride, or silicon nitride oxide may be deposited into the first trench 701 and a planarization process, such as chemical mechanical polishing, may be subsequently performed to remove excess filling material until a top surface of the substrate 101 is exposed so as to form the isolation layer 107.

With reference to FIGS. 6 and 7, the isolation layer 107 may define the plurality of active areas AA. In some embodiments, the plurality of active areas AA may extend in a direction diagonal with respect to the X axis and the Y axis from a top-view perspective.

It should be noted that each of the active areas AA may comprise a portion of the substrate 101 and a space above the portion of the substrate 101. Describing an element as being disposed on the active area AA means that the element is disposed on a top surface of the portion of the substrate 101. Describing an element as being disposed in the active area AA means that the element is disposed in the portion of the substrate 101; however, a top surface of the element may be even with the top surface of the portion of the substrate 101. Describing an element as being disposed above the active area AA means that the element is disposed above the top surface of the portion of the substrate 101.

It should be noted that, in the description of the present disclosure, a surface of an element (or a feature) located at a highest vertical level along the Z axis is referred to as a top surface of the element (or the feature). A surface of an element (or a feature) located at the lowest vertical level along the Z axis is referred to as a bottom surface of the element (or the feature).

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIGS. 8 and 9, a plurality of word line trenches 703 may be formed in the substrate 101 to define positions of a plurality of word line structures 200 which are described below. The plurality of word line trenches 703 may be formed by a photolithography process and a subsequent etch process. In some embodiments, the plurality of word line trenches 703 may have a line shape and extend in the direction X and traverse the plurality of active areas AA from a top-view perspective. For example, each active area

AA may be intersected by two word line trenches 703. The plurality of word line trenches 703 may divide each of the plurality of active areas AA into a plurality of first regions R1 and a plurality of second regions R2. For one active area AA, one first region R1 may be formed between the two word line trenches 703, and two second regions R2 may be respectively and correspondingly formed between the isolation layer 107 and the two word line trenches 703.

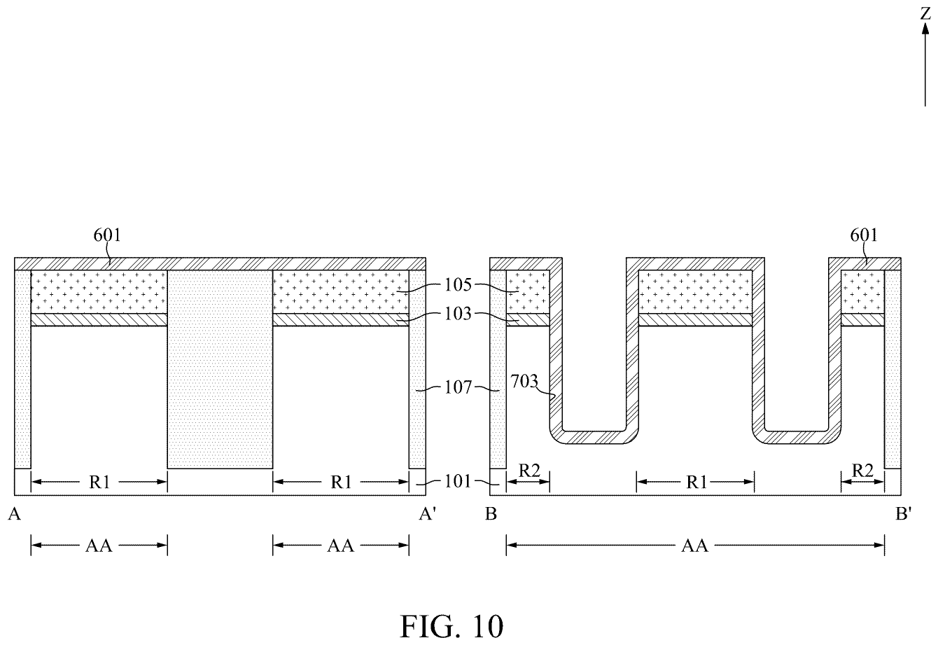

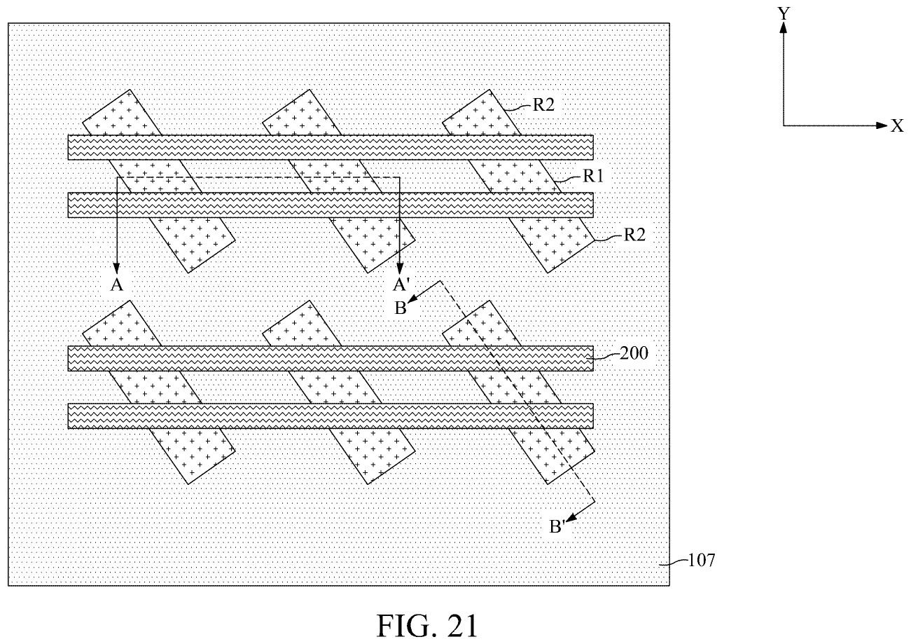

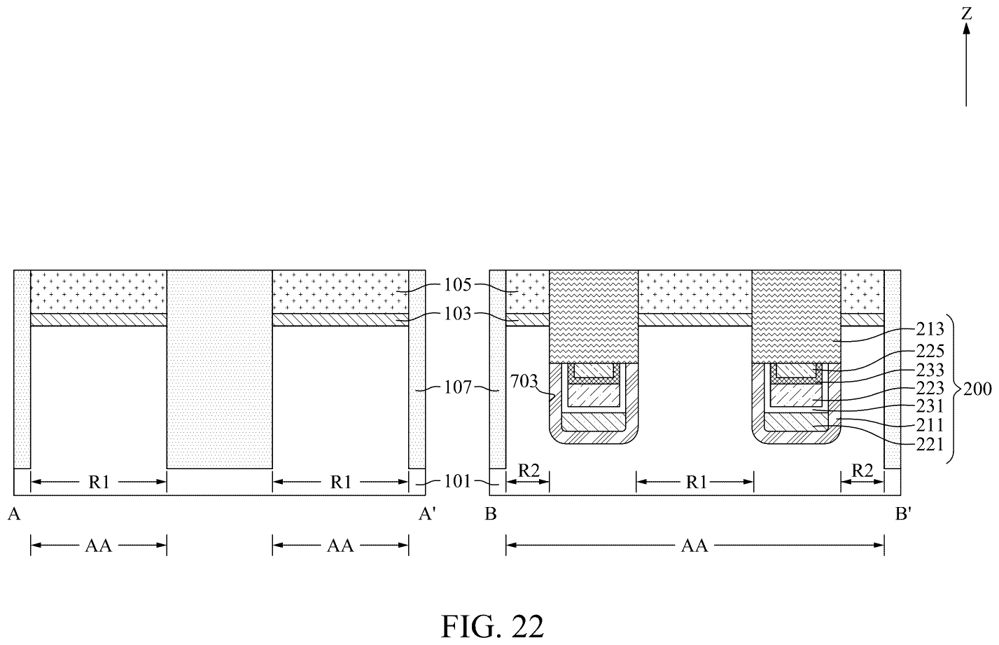

FIGS. 10 to 20 are schematic cross-sectional diagrams taken along lines A-A′ and B-B′ in FIG. 8 illustrating part of the flow for fabricating the semiconductor device 1A in accordance with one embodiment of the present disclosure. FIG. 21 is a schematic top-view diagram of an intermediate semiconductor device in accordance with one embodiment of the present disclosure. FIG. 22 is a schematic cross-sectional diagram taken along lines A-A′ and B-B′ in FIG. 21.

With reference to FIG. 1 and FIGS. 10 to 22, in step S13, a plurality of word line structures 200 may be formed in the plurality of word line trenches 703.

With reference to FIG. 10, a layer of first dielectric material 601 may be conformally formed on the pad nitride 105, on the isolation layer 107, and in the plurality of word line trenches 703. The layer of first dielectric material 601 may have a U-shaped cross-sectional profile in the plurality of word line trenches 703. In some embodiments, the layer of first dielectric material 601 may have a thickness in a range of about 1 nm to about 7 nm, including about 1 nm, about 2 nm, about 3 nm, about 4 nm, about 5 nm, about 6 nm, or about 7 nm.

In some embodiments, the layer of first dielectric material 601 may be formed by a thermal oxidation process. For example, the layer of first dielectric material 601 may be formed by oxidizing the surface of the plurality of word line trenches 703. In some embodiments, the layer of first dielectric material 601 may be formed by a deposition process such as a chemical vapor deposition or an atomic layer deposition. The first dielectric material 601 may include a high-k material, an oxide, a nitride, an oxynitride or a combination thereof. In some embodiments, after a liner polysilicon layer (not shown for clarity) is deposited, the layer of first dielectric material 601 may be formed by radical-oxidizing the liner polysilicon layer. In some embodiments, after a liner silicon nitride layer (not shown for clarity) is formed, the layer of first dielectric material 601 may be formed by radical-oxidizing the liner silicon nitride layer.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

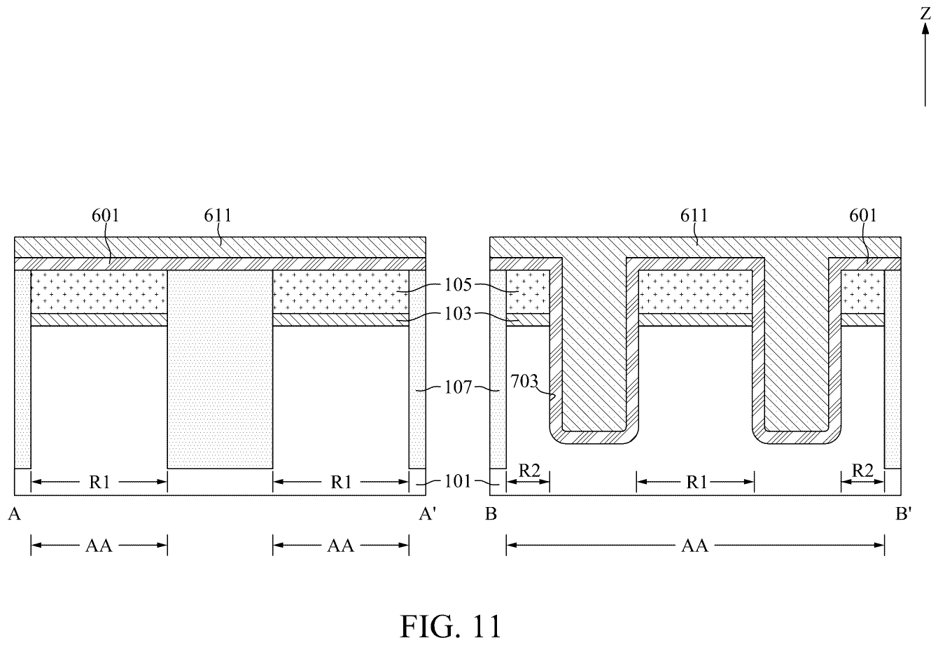

With reference to FIG. 11, a layer of first conductive material 611 may be formed on the layer of first dielectric material 601 and completely fill the plurality of word line trenches 703. In some embodiments, the first conductive material 611 may be a work function material such as, titanium, titanium nitride, silicon, silicon germanium, or a combination thereof. It should be noted that the term “work function” refers to the bulk chemical potential of a material (e.g., metal) relative to the vacuum level.

For example, in the present embodiment, the first conductive material 611 is titanium nitride and may be formed by chemical vapor deposition. In some embodiments, the formation of the layer of first conductive material 611 may include a source gas introducing step, a first purging step, a reactant flowing step, and a second purging step. The source gas introducing step, the first purging step, the reactant flowing step, and the second purging step may be collectively referred to as one cycle. Multiple cycles may be performed to obtain a desired thickness of the layer of first conductive material 611.

In detail, the intermediate semiconductor device shown in FIG. may be loaded into a reaction chamber. In the source gas introducing step, source gases containing a precursor and a reactant may be introduced to the reaction chamber containing the intermediate semiconductor device. The precursor and the reactant may diffuse across a boundary layer and reach a surface of the intermediate semiconductor device (i.e., surfaces of the layer of first dielectric material 601). The precursor and the reactant may adsorb on and subsequently migrate on the surface of the intermediate semiconductor device. The adsorbed precursor and the adsorbed reactant may react on such surface and form solid byproducts. The solid byproducts may form nuclei on the surface. The nuclei may grow into islands and the islands may merge into a continuous thin film on the surface. In the first purging step, a purge gas such as argon may be injected into the reaction chamber to purge out the gaseous byproducts, unreacted precursor, and unreacted reactant.

In the reactant flowing step, the reactant may be solely introduced to the reaction chamber to turn the continuous thin film into the layer of first conductive material 611. In the second purging step, a purge gas such as argon may be injected into the reaction chamber to purge out the gaseous byproducts and unreacted reactant.

In some embodiments, the formation of the layer of first conductive material 611 using chemical vapor deposition may be performed with the assistance of plasma. The source of the plasma may be, for example, argon, hydrogen, or a combination thereof.

For example, the precursor may be titanium tetrachloride. The reactant may be ammonia. Titanium tetrachloride and ammonia may react on the surface and form a titanium nitride film including high chloride contamination due to incomplete reaction between titanium tetrachloride and ammonia. The ammonia in the reactant flowing step may reduce the chloride content of the titanium nitride film. After the ammonia treatment, the titanium nitride film may be referred to as the layer of first conductive material 611.

Alternatively, in some other embodiments, the layer of first conductive material 611 may be formed by atomic layer deposition such as photo-assisted atomic layer deposition or liquid injection atomic layer deposition. In some embodiments, the formation of the layer of first conductive material 611 may include a first precursor introducing step, a first purging step, a second precursor introducing step, and a second purging step. The first precursor introducing step, the first purging step, the second precursor introducing step, and the second purging step may be collectively referred to as one cycle. Multiple cycles may be performed to obtain the desired thickness of the layer of first conductive material 611.

In detail, the intermediate semiconductor device shown in FIG. may be loaded into the reaction chamber. In the first precursor introducing step, a first precursor may be introduced into the reaction chamber. The first precursor may diffuse across the boundary layer and reach the surface of the intermediate semiconductor device (i.e., the surface of the layer of first dielectric material 601). The first precursor may adsorb on such surface to form a monolayer at a single atomic layer level. In the first purging step, a purge gas such as argon may be injected into the reaction chamber to purge out unreacted first precursor.

In the second precursor introducing step, a second precursor may be introduced into the reaction chamber. The second precursor may react with the monolayer and turn the monolayer into the layer of first conductive material 611. In the second purging step, a purge gas such as argon may be injected into the reaction chamber to purge out unreacted second precursor and gaseous byproduct. Compared to the chemical vapor deposition, a particle generation caused by a gas phase reaction may be suppressed because the first precursor and the second are introduced separately.

For example, the first precursor may be titanium tetrachloride. The second precursor may be ammonia. Adsorbed titanium tetrachloride may form a titanium nitride monolayer. The ammonia in the second precursor introducing step may react with the titanium nitride monolayer and turn the titanium nitride monolayer into the layer of first conductive material 611.

In some embodiments, the formation of the layer of first conductive material 611 using atomic layer deposition may be performed with the assistance of plasma. The source of the plasma may be, for example, argon, hydrogen, oxygen, or a combination thereof. In some embodiments, the oxygen source may be, for example, water, oxygen gas, or ozone. In some embodiments, co-reactants may be introduced to the reaction chamber. The co-reactants may be selected from the group consisting of hydrogen, hydrogen plasma, oxygen, air, water, ammonia, hydrazines, alkylhydrazines, boranes, silanes, ozone and a combination thereof.

In some embodiments, the formation of the layer of first conductive material 611 may be performed using the following process conditions. A temperature of the substrate may be between about 160° C. and about 300° C. A temperature of an evaporator may be about 175° C. A pressure of the reaction chamber may be about 5 mbar. A solvent for the first precursor and the second precursor may be toluene.

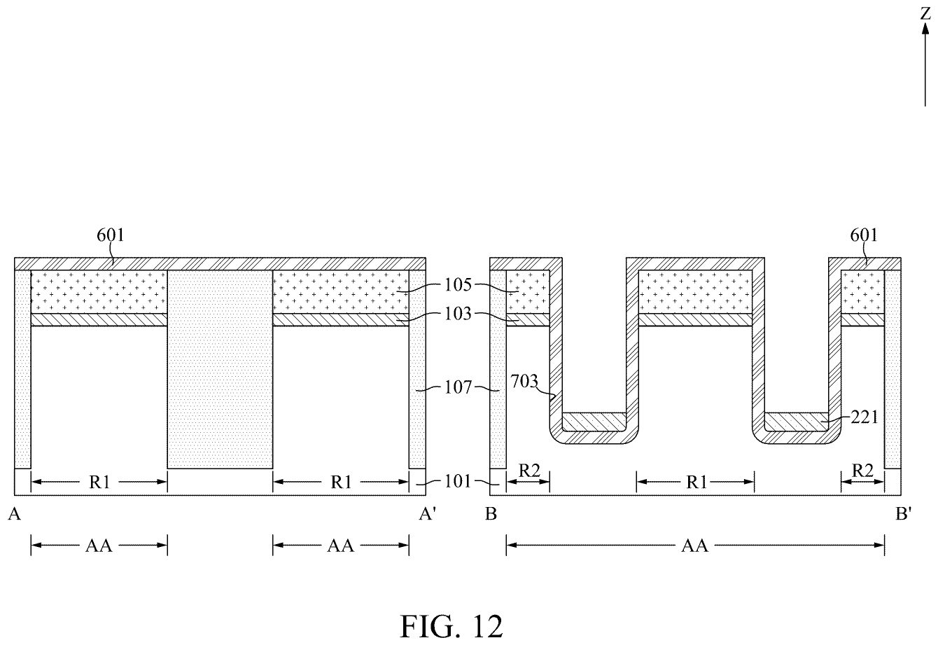

With reference to FIG. 12, a first etch-back process may be performed to remove portions of the first conductive material 611. In some embodiments, during the first etch-back process, a ratio of an etch rate of the first conductive material 611 to an etch rate of the first dielectric material 601 may be between about 100:1 and about 1.05:1, between about 15:1 and about 5:1, or between about 10:1 and about 5:1. After the first etch-back process, the remaining first conductive material 611 in the plurality of word line trenches 703 may be referred to as a plurality of bottom conductive layers 221.

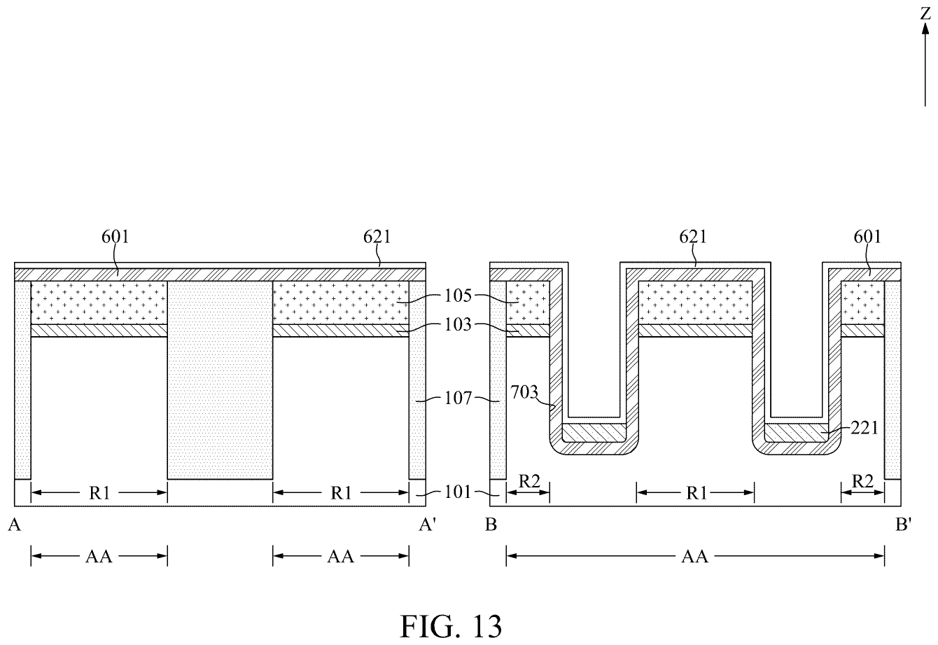

With reference to FIG. 13, a layer of first liner material 621 may be conformally formed on the layer of first dielectric material 601 and on the plurality of bottom conductive layers 221. In some embodiments, the first liner material 621 may be a material having etching selectivity to the first dielectric material 601. In some embodiments, the first dielectric material 601 may be a material having etching selectivity to the pad nitride 105. In some embodiments, the first liner material 621 may be, for example, a material including sp² hybridized carbon atoms. In some embodiments, the first liner material 621 may be, for example, a material including carbons having hexagonal crystal structures. In some embodiments, the first liner material 621 may be, for example, graphene, graphite, or the like.

In some embodiments, the layer of first liner material 621 may be formed on a catalyst substrate and then transferred onto the intermediate semiconductor device shown in FIG. 12. The catalyst substrate may include nickel, copper, cobalt, platinum, silver, ruthenium, iridium, palladium, an alloy of iron and nickel, an alloy of copper and nickel, an alloy of nickel and molybdenum, an alloy of gold and nickel, or an alloy of cobalt and copper.

In some embodiments, the layer of first liner material 621 may be formed with assistance of catalysts. The catalysts may be single crystalline metal, polycrystalline metal, binary alloy, or liquid metal. The single crystalline metal or polycrystalline metal may be, for example, nickel, copper, cobalt, platinum, silver, ruthenium, iridium, or palladium. The binary alloy may be, for example, an alloy of iron and nickel, an alloy of copper and nickel, an alloy of nickel and molybdenum, an alloy of gold and nickel, or an alloy of cobalt and copper. The liquid metal may be, for example, liquid gallium, liquid indium, or liquid copper.

In some embodiments, a catalytic conductive layer (not shown for clarity) may be conformally formed on the layer of first dielectric material 601 and on the plurality of bottom conductive layers 221. The layer of first liner material 621 may be formed on the catalytic conductive layer. The catalytic conductive layer may include nickel, copper, cobalt, platinum, silver, ruthenium, iridium, palladium, an alloy of iron and nickel, an alloy of copper and nickel, an alloy of nickel and molybdenum, an alloy of gold and nickel, or an alloy of cobalt and copper.

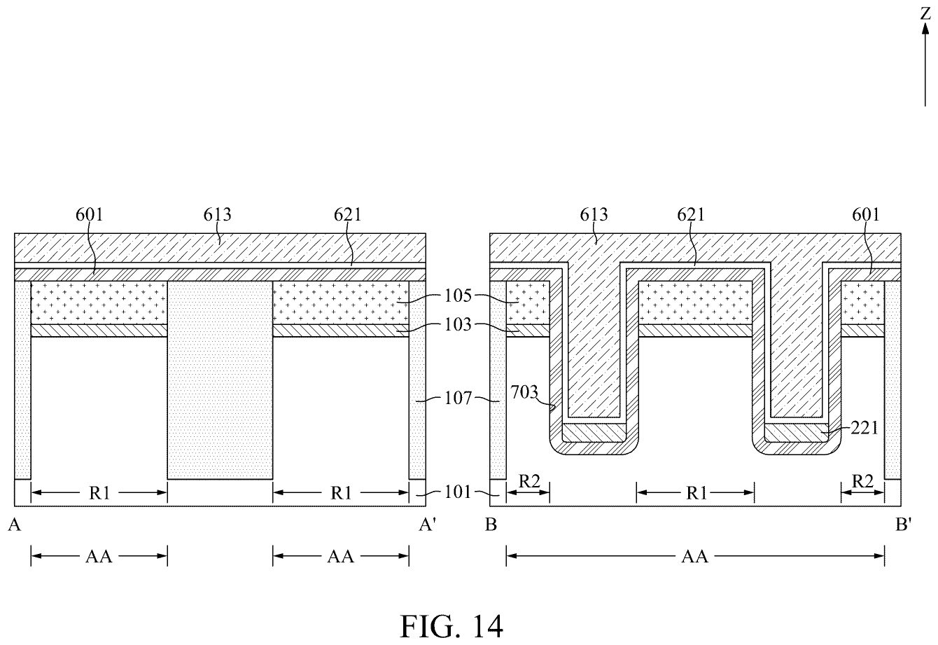

With reference to FIG. 14, a layer of second conductive material 613 may be formed on the layer of first liner material 621 and may completely fill the plurality of word line trenches 703. In some embodiments, the second conductive material 613 may be, for example, tungsten, tungsten nitride, or a combination thereof. In some embodiments, the layer of second conductive material 613 may be formed by, for example, a pulse nucleation method, chemical vapor deposition, physical vapor deposition, or another applicable deposition process. In some embodiments, a planarization process, such as chemical mechanical polishing, may be performed to remove excess material and provide a substantially flat surface for subsequent processing steps.

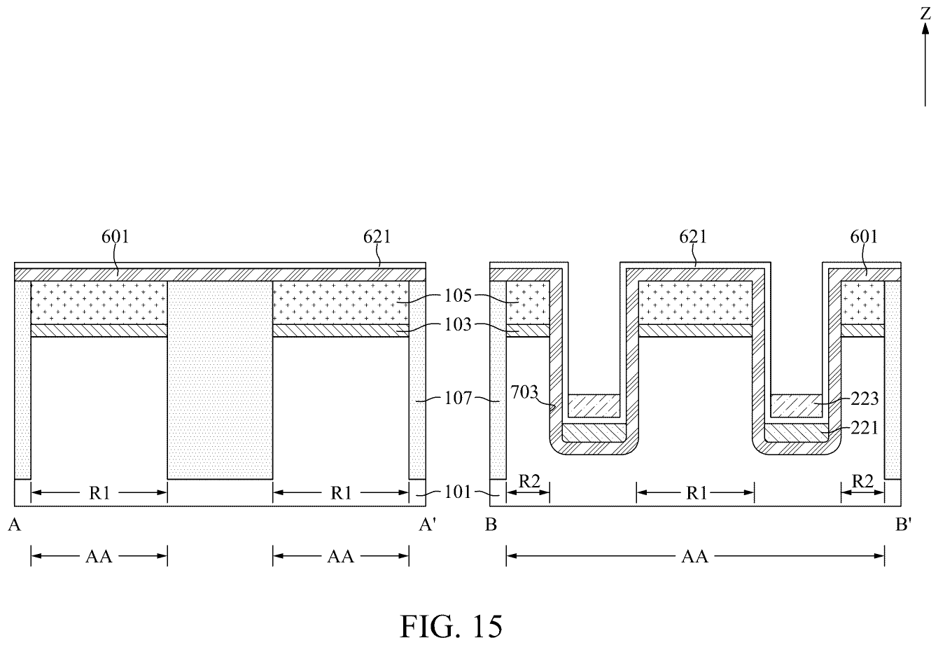

With reference to FIG. 15, a second etch-back process may be performed to remove portions of the second conductive material 613. In some embodiments, during the second etch-back process, a ratio of an etch rate of the second conductive material 613 to an etch rate of the first liner material 621 may be between about 100:1 and about 1.05:1, between about 15:1 and about 2:1, or between about 10:1 and about 2:1. After the second etch-back process, the remaining second conductive material 613 in the plurality of word line trenches 703 may be referred to as a plurality of middle conductive layers 223.

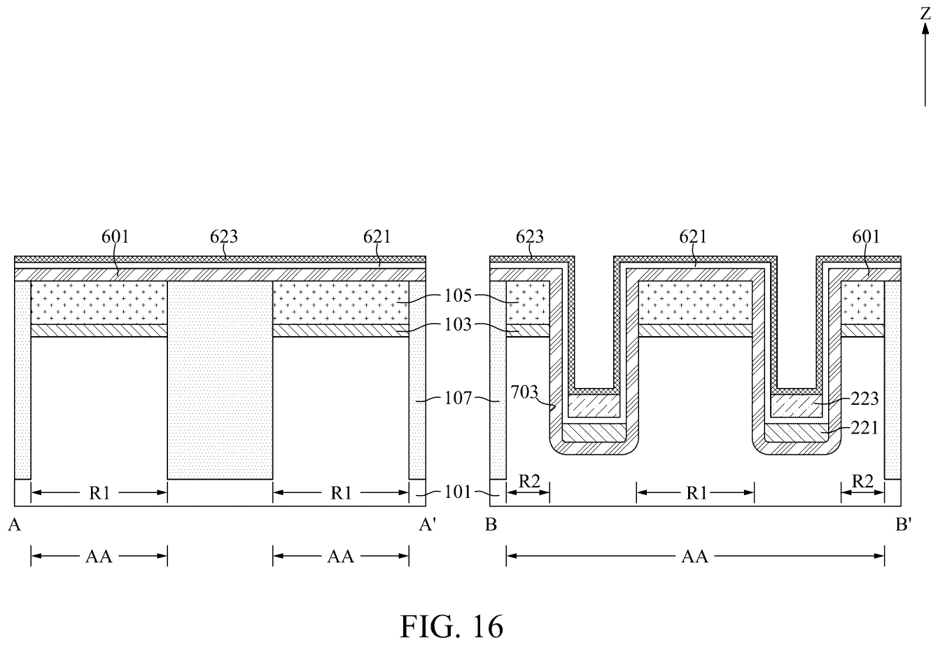

With reference to FIG. 16, a layer of second liner material 623 may be conformally formed on the layer of first liner material 621 and on the plurality of middle conductive layers 223. In some embodiments, the second liner material 623 may be a material having etching selectivity to the first dielectric material 601. In some embodiments, the second liner material 623 may be a same material as the first liner material 621. In some embodiments, the second liner material 623 may be a material having etching selectivity to the pad nitride 105. In some embodiments, the second liner material 623 may be, for example, a material including sp² hybridized carbon atoms. In some embodiments, the second liner material 623 may be, for example, a material including carbons having hexagonal crystal structures. In some embodiments, the second liner material 623 may be, for example, graphene, graphite, or the like.

In some embodiments, the layer of second liner material 623 may be formed on a catalyst substrate and then transferred onto the intermediate semiconductor device shown in FIG. 15. The catalyst substrate may include nickel, copper, cobalt, platinum, silver, ruthenium, iridium, palladium, an alloy of iron and nickel, an alloy of copper and nickel, an alloy of nickel and molybdenum, an alloy of gold and nickel, or an alloy of cobalt and copper.

In some embodiments, the layer of second liner material 623 may be formed with assistance of catalysts. The catalysts may be single crystalline metal, polycrystalline metal, binary alloy, or liquid metal. The single crystalline metal or polycrystalline metal may be, for example, nickel, copper, cobalt, platinum, silver, ruthenium, iridium, or palladium. The binary alloy may be, for example, an alloy of iron and nickel, an alloy of copper and nickel, an alloy of nickel and molybdenum, an alloy of gold and nickel, or an alloy of cobalt and copper. The liquid metal may be, for example, liquid gallium, liquid indium, or liquid copper.

In some embodiments, a catalytic conductive layer (not shown for clarity) may be conformally formed on the layer of first liner material 621 and on the plurality of middle conductive layers 223. The layer of second liner material 623 may be formed on the catalytic conductive layer. The catalytic conductive layer may include nickel, copper, cobalt, platinum, silver, ruthenium, iridium, palladium, an alloy of iron and nickel, an alloy of copper and nickel, an alloy of nickel and molybdenum, an alloy of gold and nickel, or an alloy of cobalt and copper.

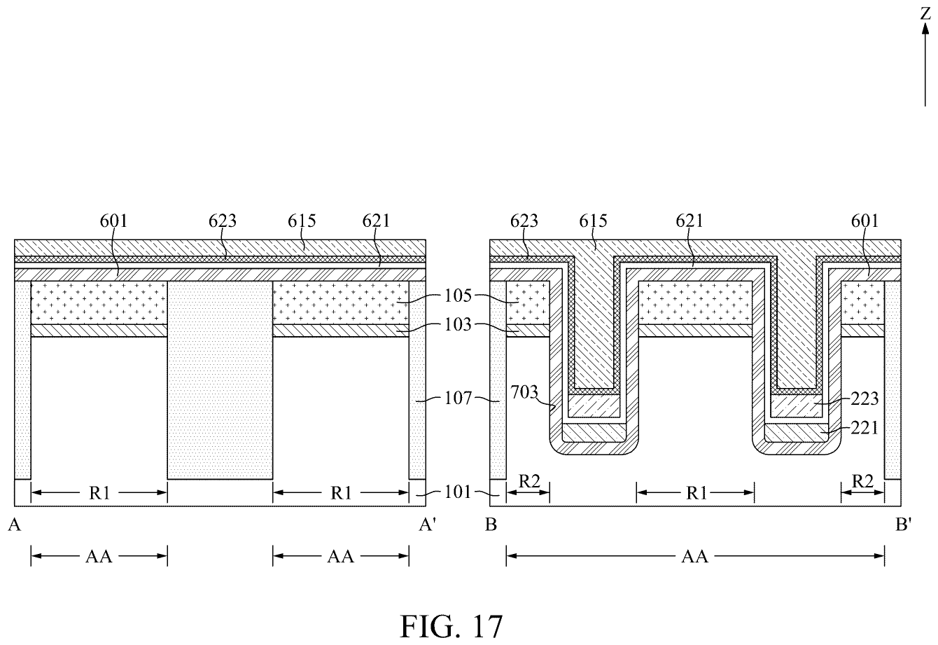

With reference to FIG. 17, a layer of third conductive material 615 may be formed on the layer of second liner material 623 and may completely fill the plurality of word line trenches 703. A planarization process, such as chemical mechanical polishing, may be performed to remove excess material and provide a substantially flat surface for subsequent processing steps. In some embodiments, the third conductive material 615 may be, for example, molybdenum or other applicable conductive materials.

In some embodiments, the third conductive material 615 may be formed by a chemical vapor deposition process. For example, the intermediate semiconductor device shown in FIG. 16 may be exposed to a molybdenum precursor and a reactant. In some embodiments, the reactant may flow continuously while a flow of the molybdenum precursor to the chamber may be turned on and off.

In some embodiments, the molybdenum precursor may include a molybdenum halide. In some embodiments, the molybdenum halide may include molybdenum fluoride, molybdenum chloride, or a combination thereof. In some embodiments, the molybdenum precursor may be flowed over the intermediate semiconductor device shown in FIG. 16 using a carrier gas. In some embodiments, the carrier gas may be flowed through an ampoule including the molybdenum precursor. In some embodiments, the carrier gas may be an inert gas. In some embodiments, the inert gas may include one or more of N₂, Ar, and He.

In some embodiments, a flow rate of the molybdenum precursor may be in a range of from 100 slm to 1000 slm, from 100 slm to 700 slm, from 100 slm to 400 slm, from 400 slm to 1000 slm, from 400 slm to 700 slm, or from 700 slm to 1000 slm. In some embodiments, a duration of the molybdenum precursor may be in a range of from 0.3 seconds to 5 seconds, from 0.3 seconds to 3 seconds, from 0.3 seconds to 1 second, from 1 second to 5 seconds, from 1 second to 3 seconds, or from 3 seconds to 5 seconds.

In some embodiments, the intermediate semiconductor device shown in FIG. 16 may be exposed to a continuous flow or a plurality of pulses of the molybdenum precursor. In some embodiments, the plurality of pulses of the molybdenum precursor may have a pause time in a range of from 0.3 seconds to 30 seconds, from 0.3 seconds to 10 seconds, from 0.3 seconds to 5 seconds, from 0.3 seconds to 1 second, from 0.5 seconds to 5 seconds, from 1 second to 30 seconds, from 1 second to 10 seconds, from 1 second to 5 seconds, from 5 seconds to seconds, from 5 seconds to 10 seconds, or from 10 seconds to 30 seconds.

In some embodiments, each of the plurality of pulses of the molybdenum precursor may be applied for a time duration in a range of from 0.3 seconds to 5 seconds, from 0.3 seconds to 3 seconds, from 0.3 seconds to 1 second, from 1 second to 5 seconds, from 1 second to 3 seconds, or from 3 seconds to 5 seconds. In some embodiments, at least one of the plurality of pulses of the molybdenum precursor may be applied for a time duration in a range of from 0.3 seconds to 5 seconds, from 0.3 seconds to 3 seconds, from 0.3 seconds to 1 second, from 1 second to 5 seconds, from 1 second to 3 seconds, or from 3 seconds to 5 seconds.

In some embodiments, the reactant may include an oxidizing agent, a reducing agent, or a combination thereof. In some embodiments, the reactant may include hydrogen, ammonia, silane, polysilane, or a combination thereof. In some embodiments, silane may be selected from one or more of disilane, trisilane, tetrasilane, higher order silanes, and substituted silane. In some embodiments, the first reactant may be flowed over the intermediate semiconductor device shown in FIG. 16 using a carrier gas. In some embodiments, the carrier gas may be an inert gas. In some embodiments, the inert gas may include one or more of N₂, Ar, and He.

In some embodiments, a flow rate of the reactant may be in a range of from 0.5 slm to 15 slm, from 0.5 slm to 10 slm, from 0.5 slm to 5 slm, from 5 slm to 15 slm, from 5 slm to 10 slm, or from 10 slm to slm. In some embodiments, a duration of the reactant may be in a range of from 0.5 seconds to 10 seconds, from 0.5 seconds to 5 seconds, from 0.5 seconds to 1 second, from 1 second to 10 seconds, from 1 second to 5 seconds, or from 5 seconds to 10 seconds.

In some embodiments, the intermediate semiconductor device shown in FIG. 16 may be exposed to a continuous flow or a plurality of pulses of the reactant. In some embodiments, the plurality of pulses of the reactant may have a pause time in a range of from 0.3 seconds to seconds, from 0.3 seconds to 10 seconds, from 0.3 seconds to 5 seconds, from 0.3 seconds to 1 second, from 0.5 seconds to 5 seconds, from 1 second to 30 seconds, from 1 second to 10 seconds, from 1 second to 5 seconds, from 5 seconds to 30 seconds, from 5 seconds to seconds, or from 10 seconds to 30 seconds.

In some embodiments, each of the plurality of pulses of the reactant may be applied for a time duration in a range of from 0.5 seconds to 10 seconds, from 0.5 seconds to 5 seconds, from 0.5 seconds to 1 second, from 1 second to 10 seconds, from 1 second to 5 seconds, or from 5 seconds to 10 seconds. In some embodiments, at least one of the plurality of pulses of the reactant may be applied for a time duration in a range of from 0.5 seconds to 10 seconds, from 0.5 seconds to 5 seconds, from 0.5 seconds to 1 second, from 1 second to 10 seconds, from 1 second to 5 seconds, or from 5 seconds to 10 seconds.

In some embodiments, the layer of third conductive material 615 may be formed at a pressure in a range of from 2 Torr to 60 Torr, from 2 Torr to 40 Torr, from 2 Torr to 20 Torr, from 20 Torr to 60 Torr, from 20 Torr to 40 Torr, or from 40 Torr to 60 Torr. In some embodiments, the layer of third conductive material 615 may be formed at a temperature in a range of from 350° C. to 550° C., from 350° C. to 500° C., from 350° C. to 450° C., from 350° C. to 400° C., from 400° C. to 550° C., from 400° C. to 500° C., from 400° C. to 450° C., from 450° C. to 550° C., from 450° C. to 500° C., or from 500° C. to 550° C.

In some embodiments, an optional annealing process may be performed after the formation of the layer of third conductive material 615. In some embodiments, the annealing process may be performed at a temperature greater than the temperature of the formation of the layer of third conductive material 615. In some embodiments, the annealing process may be performed at temperatures in a range of from 100° C. to 550° C., from 100° C. to 450° C., from 100° C. to 350° C., from 100° C. to 250° C., from 200° C. to 550° C., from 200° C. to 450° C., from 200° C. to 350° C., from 300° C. to 550° C., from 300° C. to 450° C., or from 400° C. to 550° C.

In some embodiments, an environment of the annealing process may include one or more of an inert gas (e.g., molecular nitrogen, argon) and a reducing gas (e.g., molecular hydrogen or ammonia).

In some embodiments, a duration of the annealing process may be in a range of from 1 hour to 24 hours, from 1 hour to 20 hours, from 1 hour to 15 hours, from 1 hour to 10 hours, from 1 hour to 5 hours, from 5 hours to 24 hours, from 5 hours to 20 hours, from 5 hours to 15 hours, from 5 hours to 10 hours, from 10 hours to 24 hours, from hours to 20 hours, from 10 hours to 15 hours, from 15 hours to 24 hours, from 15 hours to 20 hours, or from 20 hours to 24 hours. The annealing process may increase a density, decrease a resistivity, and/or increase a purity of the layer of third conductive material 615.

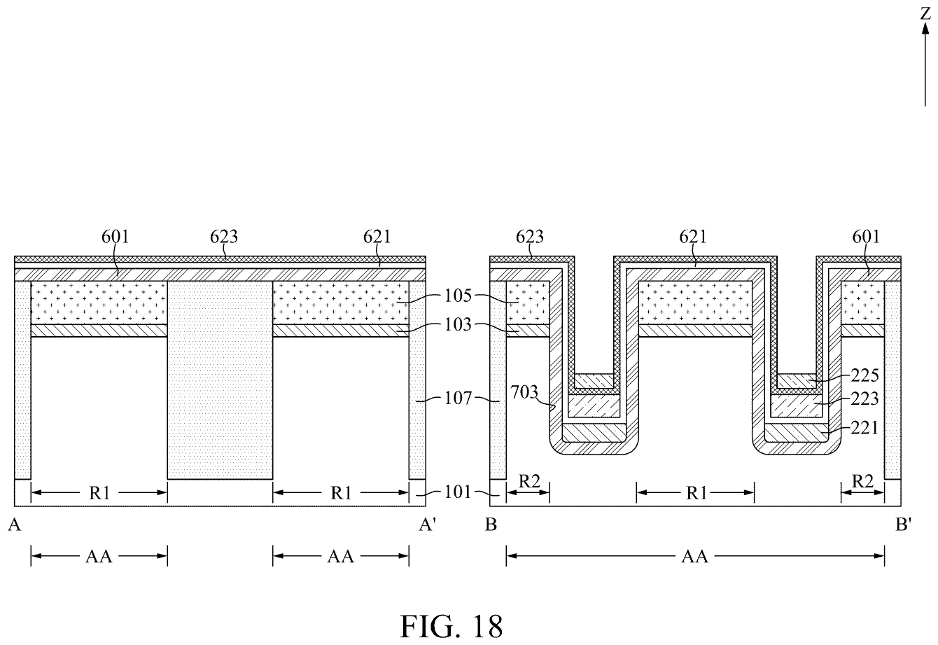

With reference to FIG. 18, a third etch-back process may be performed to remove portions of the third conductive material 615. In some embodiments, during the third etch-back process, a ratio of an etch rate of the third conductive material 615 to an etch rate of the second liner material 623 may be between about 100:1 and about 1.05:1, between about 15:1 and about 2:1, or between about 10:1 and about 2:1.

After the third etch-back process, the remaining third conductive material 615 in the plurality of word line trenches 703 may be referred to as a plurality of top conductive layers 225.

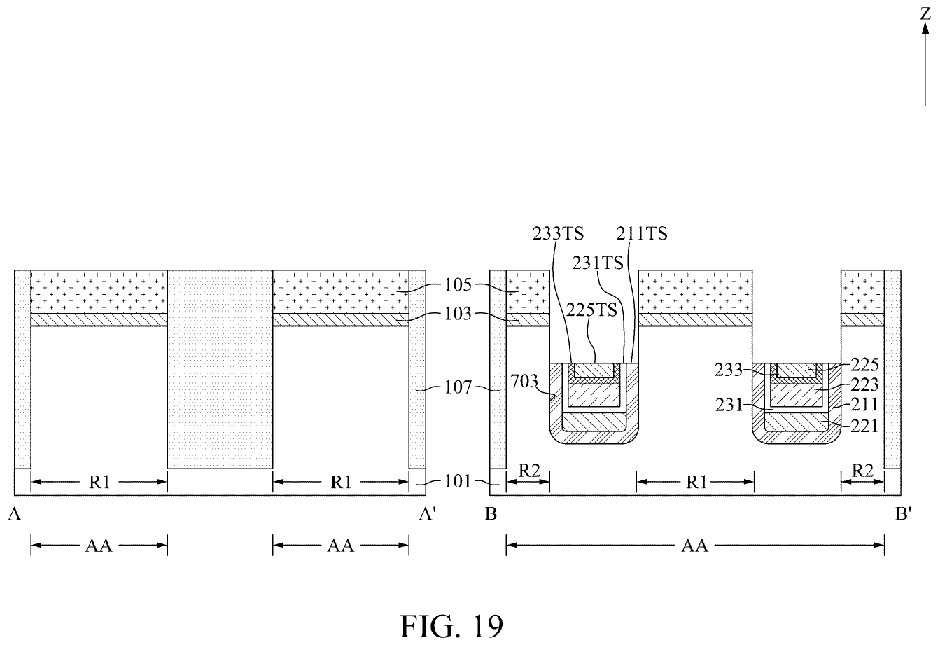

With reference to FIG. 19, a removal process may be performed to remove portions of the second liner material 623, the first liner material 621, and the first dielectric material 601. In some embodiments, the removal process may be a multi-stage etching process. For example, the removal process may be a two-stage anisotropic dry etching process. The etching chemistry may be different for each stage to provide different etching selectivities.

In some embodiments, during a first stage of the removal process, a ratio of an etch rate of the second liner material 623 (and the first liner material 621) to an etch rate of the first dielectric material 601 may be between about 100:1 and about 1.05:1, between about 15:1 and about 2:1, or between about 10:1 and about 2:1. In some embodiments, during the first stage of the removal process, a ratio of a ratio of the etch rate of the second liner material 623 (and the first liner material 621) to an etch rate of the plurality of top conductive layers 225 may be between about 100:1 and about 1.05:1, between about 15:1 and about 2:1, or between about 10:1 and about 2:1.

In some embodiments, during a second stage of the removal process, a ratio of an etch ratio of the first dielectric material 601 to an etch rate of the pad nitride 105 may be between about 100:1 and about 1.05:1, between about 15:1 and about 2:1, or between about 10:1 and about 2:1. In some embodiments, during the second stage of the removal process, a ratio of the etch rate of the first dielectric material 601 to an etch rate of the plurality of top conductive layers 225 may be between about 100:1 and about 1.05:1, between about 15:1 and about 2:1, or between about 10:1 and about 2:1.

With reference to FIG. 19, after the removal process, the remaining second liner material 623 in the plurality of word line trenches 703 may be referred to as a plurality of top liner layers 233. The top liner layers 233 may have a U-shaped cross-sectional profile. The remaining first liner material 621 in the plurality of word line trenches 703 may be referred to as a plurality of bottom liner layers 231. The bottom liner layers 231 may have a U-shaped cross-sectional profile. The remaining first dielectric material 601 in the plurality of word line trenches 703 may be referred to as a plurality of word line dielectric layers 211. The plurality of word line dielectric layers 211 may have a U-shaped cross-sectional profile.

In some embodiments, top surfaces 211TS of the plurality of word line dielectric layers 211, top surfaces 231TS of the plurality of bottom liner layers 231, top surfaces 233TS of the plurality of top liner layers 233, and top surfaces 225TS of the plurality of top conductive layers 225 may be substantially coplanar.

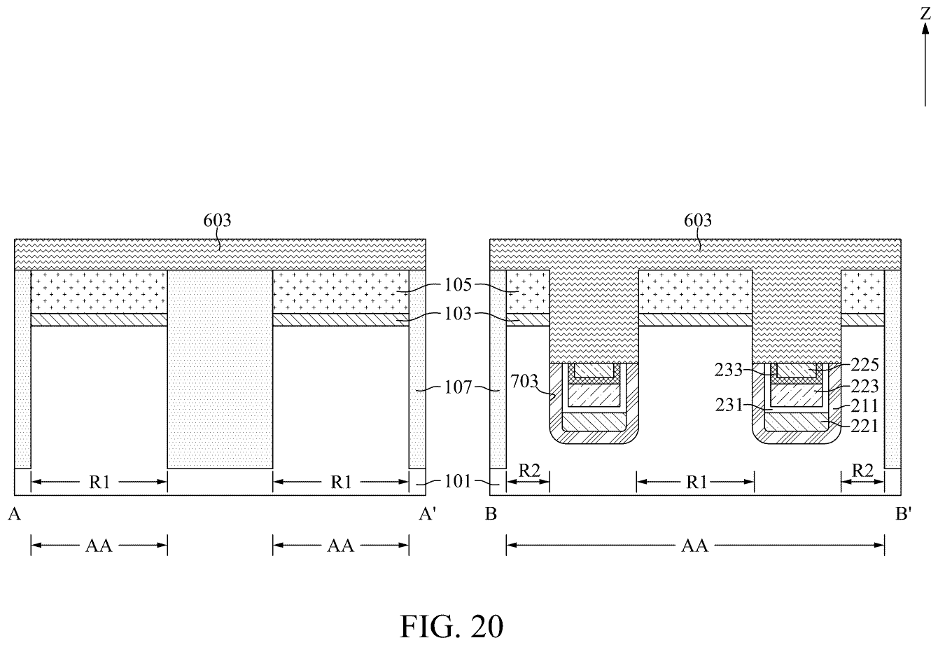

With reference to FIG. 20, a layer of capping material 603 may be formed to completely fill the plurality of word line trenches 703. In some embodiments, the capping material 603 may be, for example, silicon oxide, silicon nitride, silicon oxynitride, silicon nitride oxide, or other applicable insulating materials. In some embodiments, the capping material 603 may be, for example, germanium oxide. In some embodiments, the layer of capping material 603 may be formed by, for example, chemical vapor deposition, atomic layer deposition, or another applicable deposition process.

For example, when the layer of capping material 603 is formed by atomic layer deposition, the atomic layer deposition process may include alternately and sequentially contacting the intermediate semiconductor device shown in FIG. 19 with a vapor phase germanium precursor and an oxygen-containing reactant (also referred to as the oxygen source), such that a layer of the germanium precursor is formed on the surface of the intermediate semiconductor device, and the oxygen-containing reactant subsequently reacts with the germanium precursor to form the layer of capping material 603.

In detail, the germanium precursor may be conducted into the process chamber containing the intermediate semiconductor device shown in FIG. 19 via vapor phase pulse and brought into contact with the surface of the intermediate semiconductor device. The excess germanium precursor and reaction byproducts, if any, may be removed from the intermediate semiconductor device, from the surface of the intermediate semiconductor device, and from proximity to the intermediate semiconductor device.

In some embodiments, the excess germanium precursor and reaction byproducts, if any, may be removed by purging. Purging may be accomplished, for example, with a pulse of inert gas such as nitrogen or argon. Purging the process chamber means that vapor phase precursors and/or vapor phase byproducts are removed from the process chamber such as by evacuating the process chamber with a vacuum pump and/or by replacing the gas inside the process chamber with an inert gas such as argon or nitrogen. In some embodiments, purging times may be between about 0.05 seconds and about 20 seconds, between about 1 second and about 10 seconds, or between about 1 second and about 20 seconds.

The oxygen source may be pulsed into the process chamber where it reacts with the germanium precursor on the surface of the intermediate semiconductor device to form the layer of capping material 603 comprising germanium oxide. Excess oxygen source and gaseous by-products of the surface reaction may be removed from the intermediate semiconductor device, for example by purging them out of the process chamber with the aid of an inert gas.

The steps of pulsing and removing may be repeated until the layer of capping material 603 reaches a desired thickness on the intermediate semiconductor device.

In some embodiments, the germanium precursor is not a halide. In some embodiments, the germanium precursor may include a halogen in at least one ligand, but not in all ligands. In some embodiments, the germanium precursor may include germanium ethoxide or tetrakis (dimethylamino) germanium.

In some embodiments, the oxygen source may be water, ozone, oxygen plasma, oxygen radicals, or oxygen atoms. In some embodiments, the oxygen source is not water. In some embodiments, the germanium precursor employed may be solid, liquid, or gaseous material at standard temperature and pressure, provided that the germanium precursor is in vapor phase before it is conducted into the process chamber and brought into contact with the intermediate semiconductor device.

It should be noted that, in the present disclosure, “pulsing” a vaporized precursor onto a feature means that the precursor vapor is conducted into the process chamber for a limited period of time. In some embodiments, the germanium precursor may be pulsed for between about 0.05 seconds and about 10 seconds, between about 0.1 seconds and about 5 seconds, or between about 0.3 seconds and about 3 seconds. In some embodiments, the oxygen source may be pulsed for between about 0.05 seconds and about 10 seconds, between about 0.1 seconds and about 5 seconds, or between about 0.2 seconds and about 3 seconds.

In some embodiments, the oxygen source may be an oxygen-containing gas pulse and can be a mixture of oxygen and inert gas, such as nitrogen or argon. In some embodiments, the oxygen source may be a molecular oxygen-containing gas pulse. An oxygen content of the oxygen-source gas may be between about 10% and about 25%. Thus, one source of oxygen may be air.

In some embodiments, the oxygen source may be molecular oxygen. In some embodiments, the oxygen source may include an activated or excited oxygen species. In some embodiments, the oxygen source may include ozone. In some embodiments, the oxygen source may be pure ozone or a mixture of ozone, molecular oxygen, and another gas, for example an inert gas such as nitrogen or argon.

Ozone can be produced by an ozone generator, and it may be introduced into the process chamber with the aid of an inert gas, such as nitrogen, or with the aid of oxygen. In some embodiments, ozone may be provided at a concentration between about 5 vol-% and about vol-%, or between about 15 vol-% and about 25 vol-%. In some embodiments, the oxygen source may be oxygen plasma. In some embodiments, ozone or a mixture of ozone and another gas may be pulsed into the process chamber. In some embodiments, ozone may be formed inside the process chamber, for example by conducting oxygen-containing gas through an arc. In some embodiments, an oxygen-containing plasma may be formed in the process chamber. In some embodiments, the plasma may be formed upstream of the process chamber in a remote plasma generator, and plasma products may be directed to the process chamber to contact the intermediate semiconductor device.

In some embodiments, the oxygen source may be an oxygen source other than water. Thus, water is not provided in such embodiments.

In some embodiments, a temperature of the formation of the layer of capping material 603 may be between about 20° C. and about 600° C., between about 100° C. and about 400° C., or between about 150° C. and about 300° C.

In some embodiments, the layer of capping material 603 is a pure germanium oxide layer. That is, aside from minor impurities, no other metal or semi-metal elements are present in the layer of capping material 603. In some embodiments, the layer of capping material 603 may include less than 1-at % of metal or semi-metal other than germanium. In some embodiments, the layer of capping material 603 may include less than about 5-at % of any impurity other than hydrogen, less than about 3-at % of any impurity other than hydrogen, or less than about 1-at % of any impurity other than hydrogen.

With reference to FIGS. 21 and 22, a planarization process may be performed until a top surface of the pad nitride 105 is exposed. After the planarization process, the remaining capping material 603 may be referred to as a plurality of word line capping layers 213. In some embodiments, the planarization process may be an etching process, a chemical mechanical polishing process, or a combination thereof. In the current stage, the top surface of the pad nitride 105 and top surfaces of the plurality of word line capping layers 213 may be substantially coplanar.

With reference to FIGS. 21 and 22, the plurality of word line dielectric layers 211, the plurality of word line capping layers 213, the plurality of bottom conductive layers 221, the plurality of middle conductive layers 223, the plurality of top conductive layers 225, the plurality of bottom liner layers 231, and the plurality of top liner layers 233 together configure the plurality of word line structures 200.

In some embodiments, the bottom liner layer 231 and the middle conductive layer 223 may be configured to tune the work function cooperating with the bottom conductive layer 221 so as to obtain the word line structure 200 having a low resistance. As a result, performance of the word line structure 200 is improved.

By employing the word line capping layer 213 formed of germanium oxide, leakage of the word line structure 200 may be prevented and trap density may be decreased. As a result, performance of the semiconductor device 1A is improved.

In some embodiments, the plurality of word line structures 200 may have a work function greater than or equal to 4.3 eV. In some embodiments, the plurality of word line structures 200 may have a work function greater than or equal to 4.5 eV. In some embodiments, the plurality of word line structures 200 may have a work function greater than or equal to 4.3 eV, including greater than or equal to 4.4 eV, greater than or equal to 4.5 eV, greater than or equal to 4.6 eV, greater than or equal to 4.7 eV, greater than or equal to 4.8 eV, greater than or equal to 4.9 eV, greater than or equal to 5.0 eV, greater than or equal to 5.1 eV, or greater than or equal to 5.2 eV.

In some embodiments, the plurality of word line structures 200 may have a resistance less than or equal to 40 μΩ-cm, less than or equal to 30μΩ-cm, less than or equal to 25μΩ-cm, less than or equal to 20 μΩ-cm, or less than or equal to 15 μΩ-cm at a total thickness of 100 Å. In some embodiments, the plurality of word line structures 200 may have a resistance less than or equal to 20 μΩ-cm at a total thickness of 100 Å. In some embodiments, the plurality of word line structures 200 may have a resistance in a range of from 5μΩ-cm to 50μΩ-cm, from 10μΩ-cm to 40μΩ-cm, from 10μΩ-cm to 30μΩ-cm, from 10μΩ-cm to 25μΩ-cm, or from 10μΩ-cm to 20μΩ-cm at a total thickness of 100 Å.

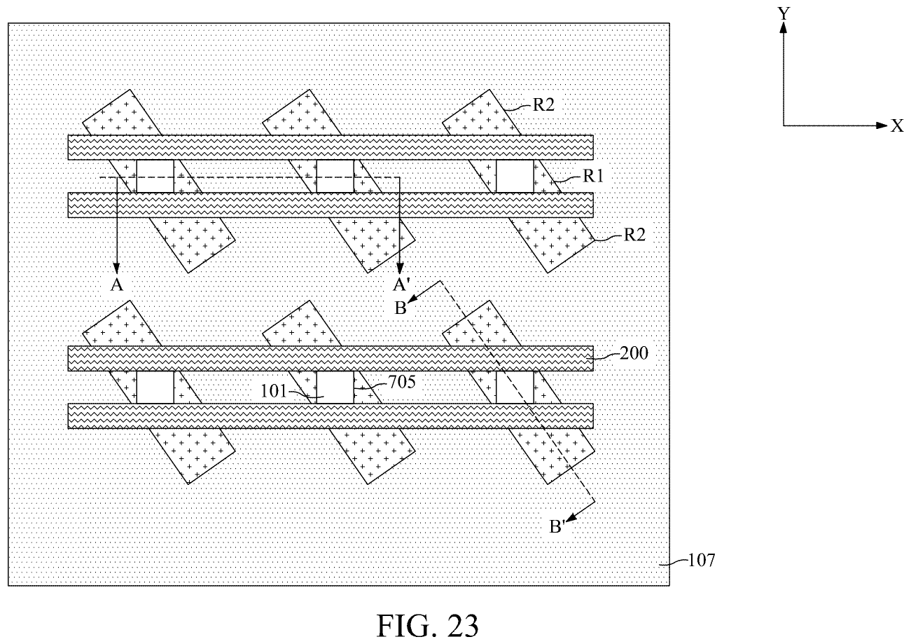

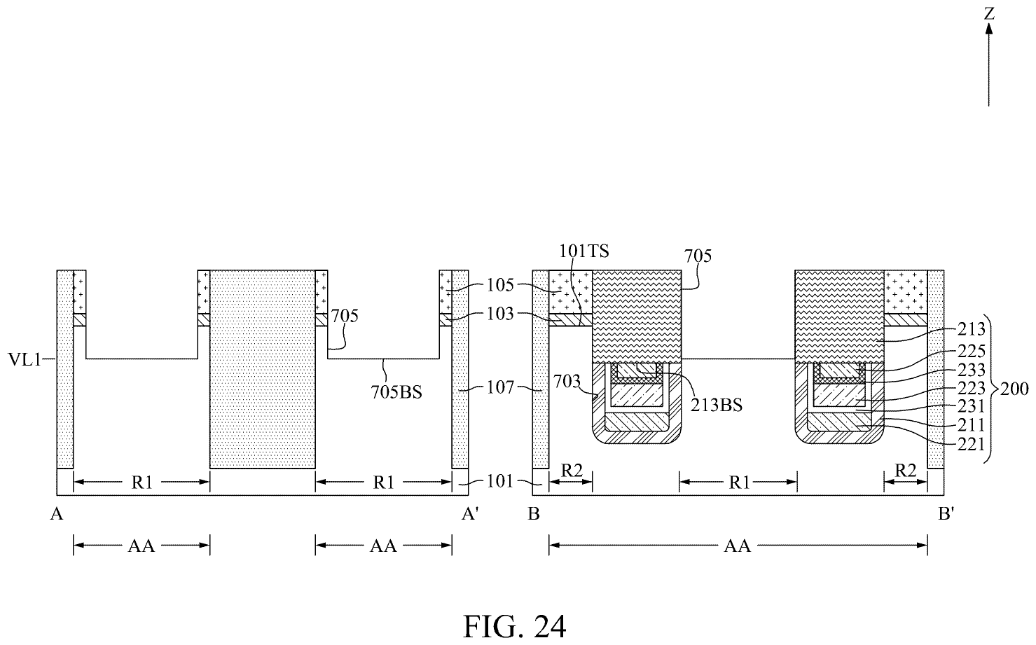

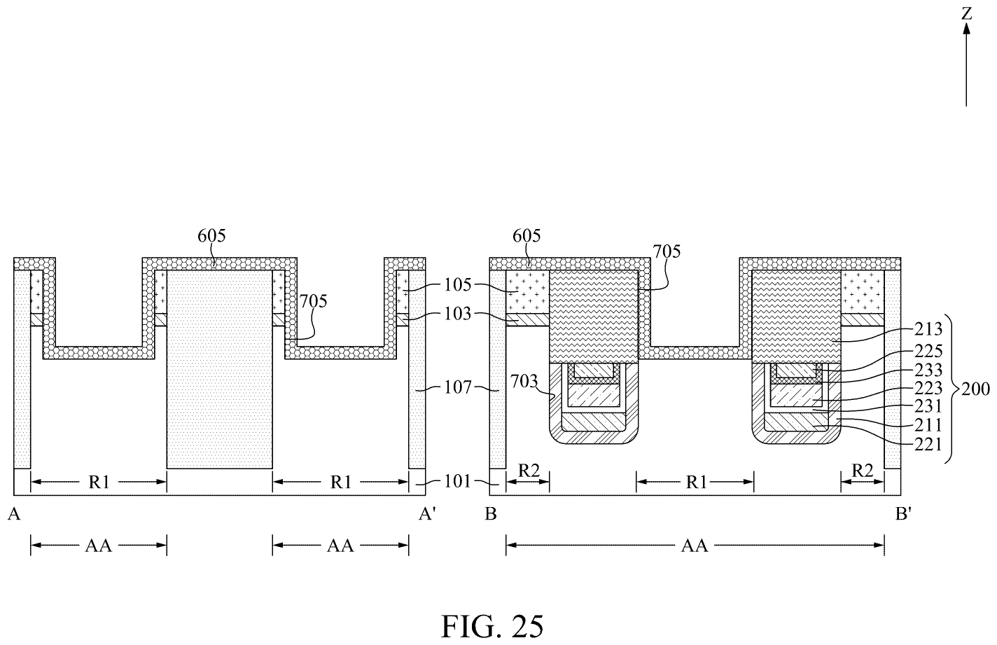

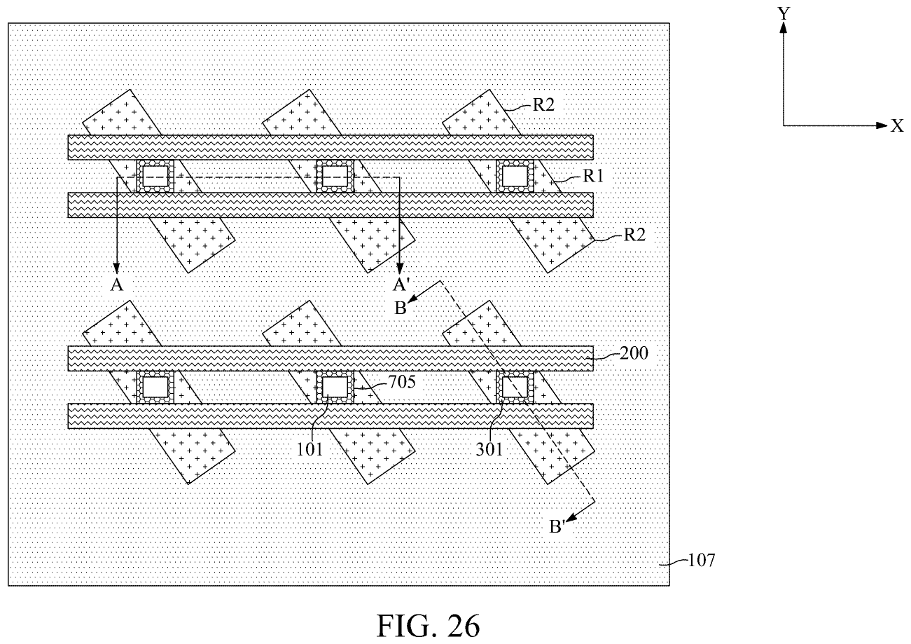

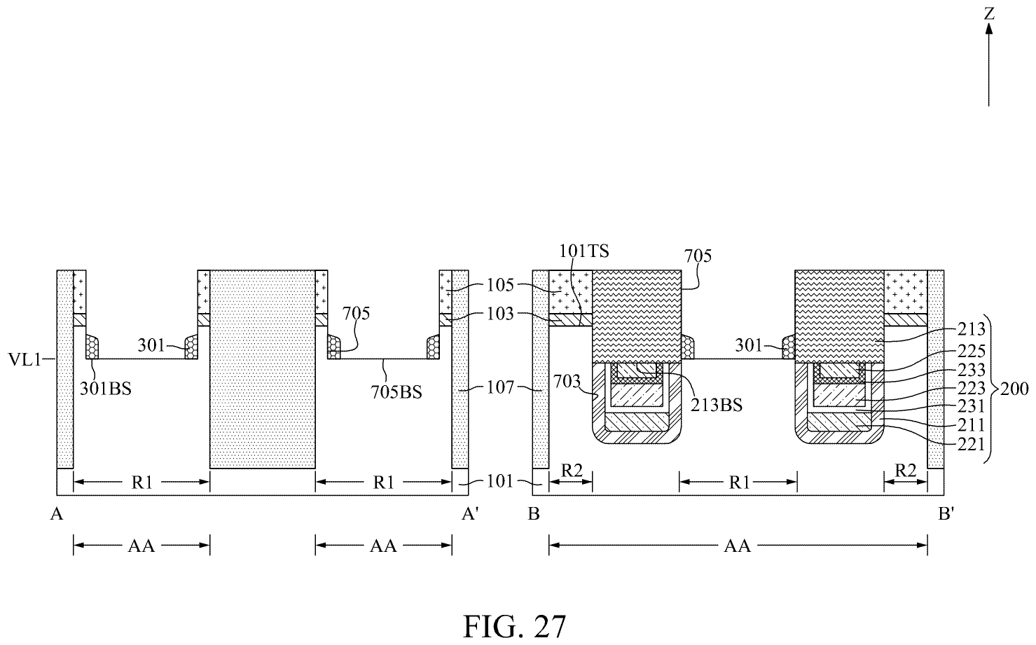

FIG. 23 is a schematic top-view diagram of an intermediate semiconductor device in accordance with one embodiment of the present disclosure. FIGS. 24 and 25 are schematic cross-sectional diagrams taken along lines A-A′ and B-B′ in FIG. 23 illustrating part of the flow for fabricating the semiconductor device 1A in accordance with one embodiment of the present disclosure. FIG. 26 is a schematic top-view diagram of an intermediate semiconductor device in accordance with one embodiment of the present disclosure. FIG. 27 is a schematic cross-sectional diagram taken along lines A-A′ and B-B′ in FIG. 26 illustrating part of the flow for fabricating the semiconductor device 1A in accordance with one embodiment of the present disclosure.

With reference to FIG. 1 and FIGS. 23 to 27, in step S15, a plurality of openings 705 may be formed in the plurality of first regions R1 and a plurality of in-recess spacers 301 may be formed in the plurality of openings 705.

With reference to FIGS. 23 and 24, the plurality of openings 705 may be formed by a photolithography process and a subsequent etching process. A bottom surface 705BS of the opening 705 may be at a vertical level VL1 between a bottom surface 213BS of the word line capping layer 213 and the top surface 101TS of the substrate 101. In some embodiments, the opening 705 may have a square cross-sectional profile from a top-view perspective, but the disclosure is not limited thereto. In some embodiments, the opening 705 may have a rectangular, a circular, or another suitably-shaped cross-sectional profile from a top-view perspective.

With reference to FIG. 25, a layer of spacer material 605 may be conformally formed on the pad nitride 105, on the isolation layer 107, on the word line capping layer 213, and in the plurality of openings 705. In some embodiments, the layer of spacer material 605 may be formed by, for example, atomic layer deposition, chemical vapor deposition, or another applicable deposition process. In some embodiments, the spacer material 605 may be a material having etching selectivity to the word line capping layer 213. In some embodiments, the spacer material 605 may be, for example, silicon oxide, silicon nitride, silicon oxynitride, silicon nitride oxide, boron nitride, silicon boron nitride, phosphorus boron nitride, boron carbon silicon nitride, or another applicable insulating material.

With reference to FIGS. 26 and 27, a spacer etching process may be performed to remove portions of the spacer material 605. The remaining spacer material 605 may be referred to as the plurality of in-recess spacers 301. In some embodiments, the spacer etching process may be, for example, an anisotropic etching process such as reactive ion etching.

In some embodiments, the in-recess spacer 301 may have a square ring-shaped cross-sectional profile from a top-view perspective, but the disclosure is not limited thereto. In some embodiments, the in-recess spacer 301 may have a rectangular ring-shaped, a ring-shaped, or other suitably-shaped cross-sectional profile from a top-view perspective.

In some embodiments, a bottom surface 301BS of the in-recess spacer 301 may be at the vertical level VL1 between the bottom surface 213BS of the word line capping layer 213 and the top surface 101TS of the substrate 101. In some embodiments, a top portion of the in-recess spacer 301 may be lower than the top surface 101TS of the substrate 101. In some embodiments, a portion of the in-recess spacer 301 extending in the direction X (from a top-view perspective) may be disposed against the word line capping layer 213 (from a cross-sectional perspective). A portion of the in-recess spacer 301 extending in the direction Y (from a top-view perspective) may be disposed against the substrate 101 (from a cross-sectional perspective).

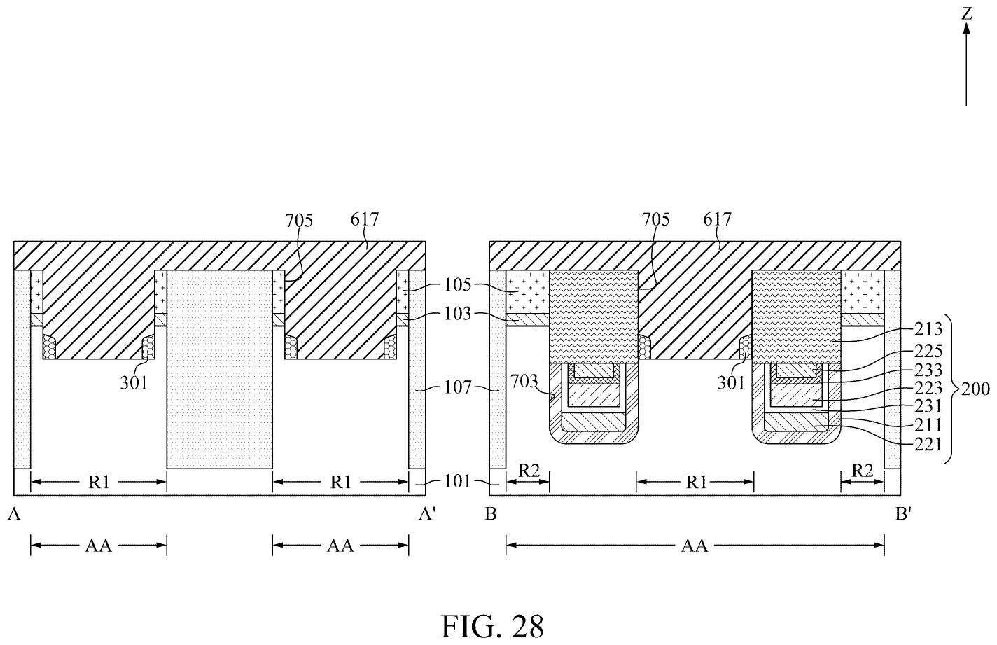

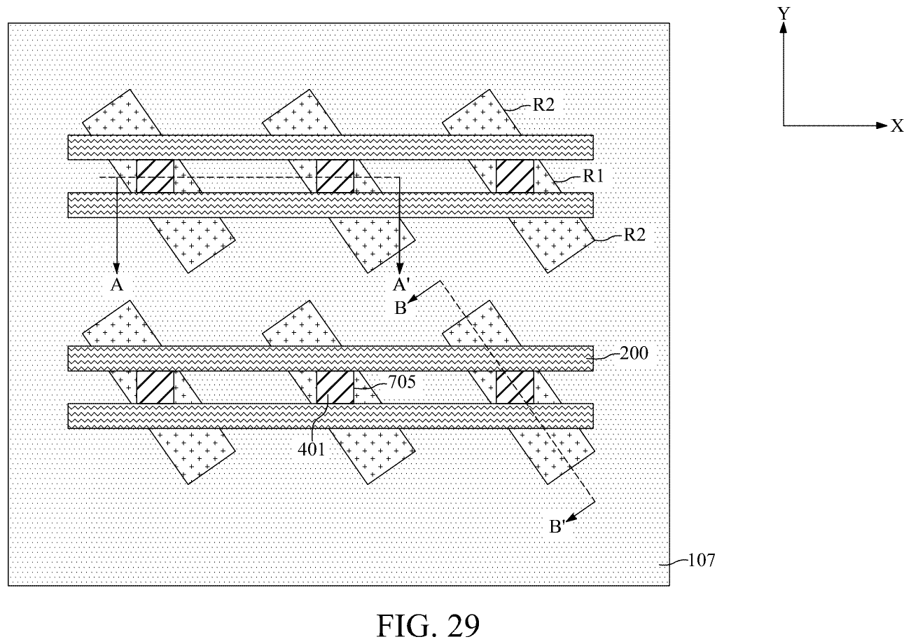

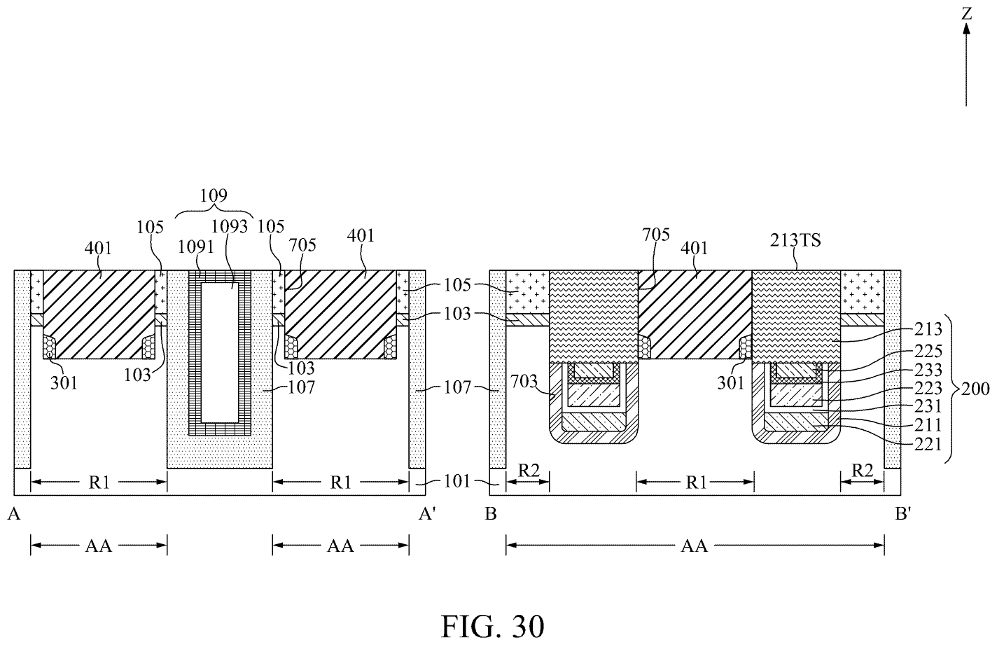

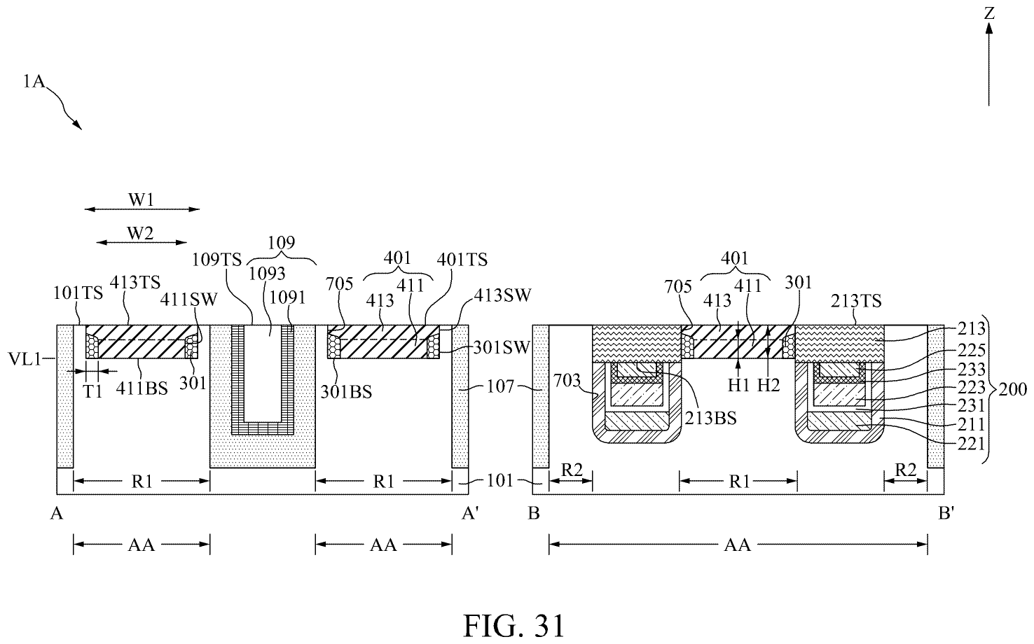

FIG. 28 is a schematic cross-sectional diagram taken along lines A-A′ and B-B′ in FIG. 26 illustrating part of the flow for fabricating the semiconductor device 1A in accordance with one embodiment of the present disclosure. FIG. 29 is a schematic top-view diagram of an intermediate semiconductor device in accordance with one embodiment of the present disclosure. FIGS. 30 and 31 are schematic cross-sectional diagrams taken along lines A-A′ and B-B′ in FIG. 29 illustrating part of the flow for fabricating the semiconductor device 1A in accordance with one embodiment of the present disclosure. With reference to FIG. 1 and FIGS. 28 to 31, in step S17, a plurality of buried conductive layers 401 may be formed in the plurality of openings 705.

With reference to FIG. 28, a layer of fourth conductive material 617 may be formed to cover the plurality of in-recess spacers 301 and to completely fill the plurality of openings 705. In some embodiments, the layer of fourth conductive material 617 may be formed by, for example, chemical vapor deposition, plasma-enhanced chemical vapor deposition, physical vapor deposition, sputtering, electroplating, electroless plating, or another applicable deposition process. In some embodiments, the fourth conductive material 617 may be, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

With reference to FIGS. 29 and 30, a planarization process may be performed until the plurality of word line capping layers 213 are exposed, so as to remove excess material and provide a substantially flat surface for subsequent processing steps. The remaining fourth conductive material 617 may be referred to as the plurality of buried conductive layers 401. In the current stage, the top surface 213TS of the word line capping layer 213, a top surface of the buried conductive layer 401, and the top surface of the pad nitride 105 may be substantially coplanar. In some embodiments, the planarization process may be an etching process, a chemical mechanical polishing process, or a combination thereof. In addition, a thermal treating process is performed. In some embodiments, during the thermal treating process, an air gap structure 109 is formed in the isolation layer 107 between two buried conductive layers 401. In some embodiments, the air gap structure 109 includes an air gap 1093 enclosed by a liner 1091. In some embodiments, the air gap structure 109 is formed between two pad nitrides 105 and between two pad oxides 103.

With reference to FIG. 31, a planarization process, such as chemical mechanical polishing, may be performed until the top surface 101TS of the substrate 101 is exposed, thus removing the pad oxide 103 and the pad nitride 105. In the current stage, the top surface 109TS of the air gap structure 109, the top surface 401TS of the buried conductive layer 401, the top surface 213TS of the word line capping layer 213, and the top surface 101TS of the substrate 101 may be substantially coplanar.

The buried conductive layer 401 may include a bottom portion 411 and a top portion 413. The bottom portion 411 may be disposed in the opening 705. A bottom surface 411BS of the bottom portion 411 may contact the substrate 101. The bottom surface 411BS of the bottom portion 411 (i.e., the bottom surface of the buried conductive layer 401) and the bottom surface 301BS of the in-recess spacer 301 may be substantially coplanar. Sidewalls 411SW of the bottom portion 411 may be surrounded by the in-recess spacer 301. The bottom surface 411BS of the bottom portion 411 may be at the vertical level VL1 higher than the bottom surface 213BS of the word line capping layer 213. Alternatively, in some embodiments, the bottom surface 411BS of the bottom portion 411 and the bottom surface 301BS of the in-recess spacer 301 may be at a vertical level (not shown) lower than the bottom surface 213BS of the word line capping layer 213.

The top portion 413 may be disposed on the bottom portion 411 and may cover the top portion of the in-recess spacer 301. A top surface 413TS of the top portion 413 (i.e., the top surface of the buried conductive layer 401), the top surface 213TS of the word line capping layer 213, and the top surface 101TS of the substrate 101 may be substantially coplanar. A sidewall 413SW of the top portion 413 and the sidewall 301SW of the in-recess spacer 301 may be substantially coplanar.

In some embodiments, a ratio of a width W1 of the bottom surface 411BS of the bottom portion 411 to a width W2 of the top surface 413TS of the top portion 413 may be between about 0.5 and about 0.95. In some embodiments, a ratio of a thickness T1 of the in-recess spacer 301 to the width W2 of the top surface 413TS of the top portion 413 may be between about 0.025 and about 0.25. In some embodiments, a ratio of a height H1 of the in-recess spacer 301 to a height H2 of the buried conductive layer 401 may be between about 0.5 and about 0.85.

An electrical field near the buried conductive layer 401 may be reduced by employing the in-recess spacer 301. Therefore, a gate-induced drain leakage (GIDL) may be reduced due to the electrical field reduction. As a result, the performance of the semiconductor device 1A is improved.

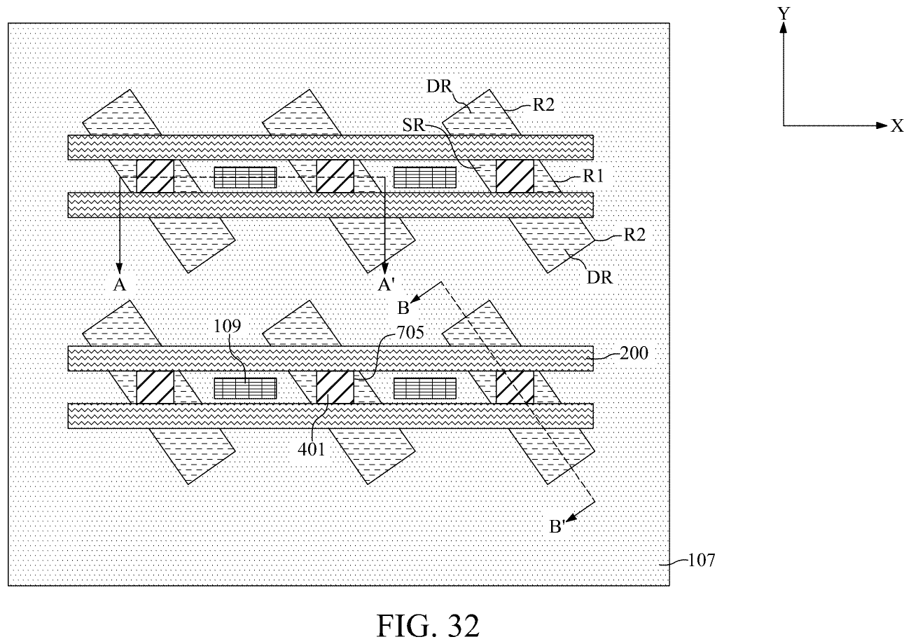

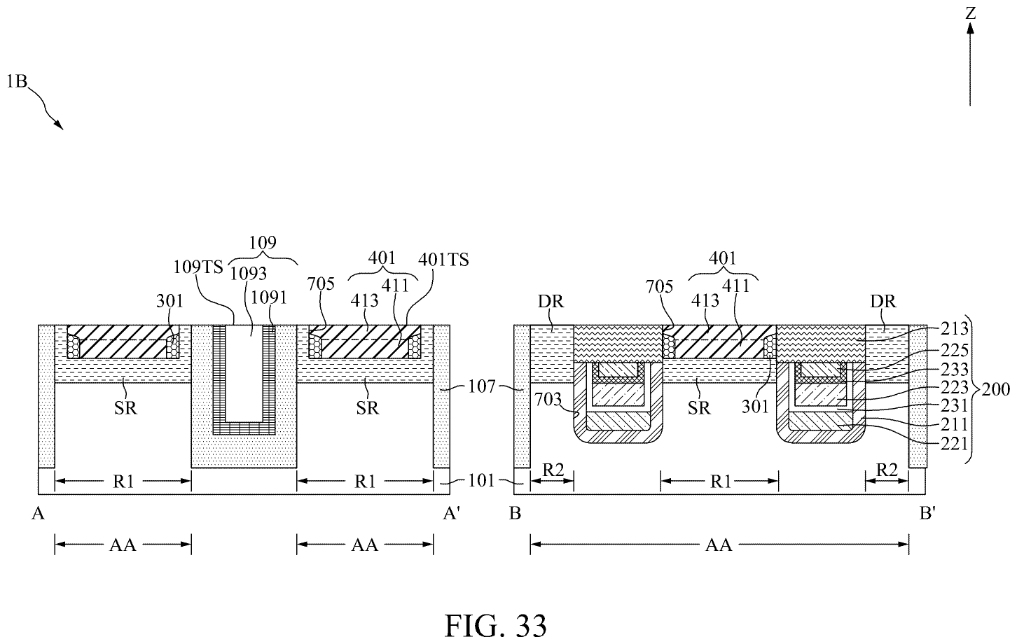

FIG. 32 is a schematic top-view diagram of an intermediate semiconductor device in accordance with another embodiment of the present disclosure. FIG. 33 is a schematic cross-sectional diagram taken along lines A-A′ and B-B′ in FIG. 32.

With reference to FIGS. 32 and 33, the semiconductor device 1B may have a structure similar to that shown in FIG. 31. Elements in FIGS. 32 and 33 that are same as or similar to elements in FIG. 31 are indicated by similar reference numbers, and duplicate descriptions are omitted.

With reference to FIGS. 32 and 33, the semiconductor device 1B may include a plurality of sources SR and a plurality of drains DR. Each of the sources SR may be disposed in a corresponding one of the plurality of first regions R1. Each of the drains DR may be disposed in a corresponding one of the plurality of second regions R2. One of the in-recess spacers 301 and one of the buried conductive layers 401 may be disposed in a corresponding one of the plurality of sources SR.

The plurality of sources SR and the plurality of drains DR may be formed by an implantation process. The implantation process may employ, for example, n-type dopants. The n-type dopants may be added to an intrinsic semiconductor to contribute free electrons to the intrinsic semiconductor. In a silicon-containing substrate, examples of n-type dopants, i.e., impurities, include but are not limited to antimony, arsenic, and phosphorous. In some embodiments, a dopant concentration of the plurality of sources SR and the plurality of drains DR may be between about 1E19 atoms/cm³ and about 1E21 atoms/cm³; although other dopant concentrations that are lesser than, or greater than, such range may also be employed in the present application.

In some embodiments, an annealing process may be performed to activate the plurality of sources SR and the plurality of drains DR. The annealing process may have a process temperature between about 800° C. and about 1250° C. The annealing process may have a process duration between about 1 millisecond and about 500 milliseconds. The annealing process may be, for example, a rapid thermal anneal, a laser spike anneal, or a flash lamp anneal.

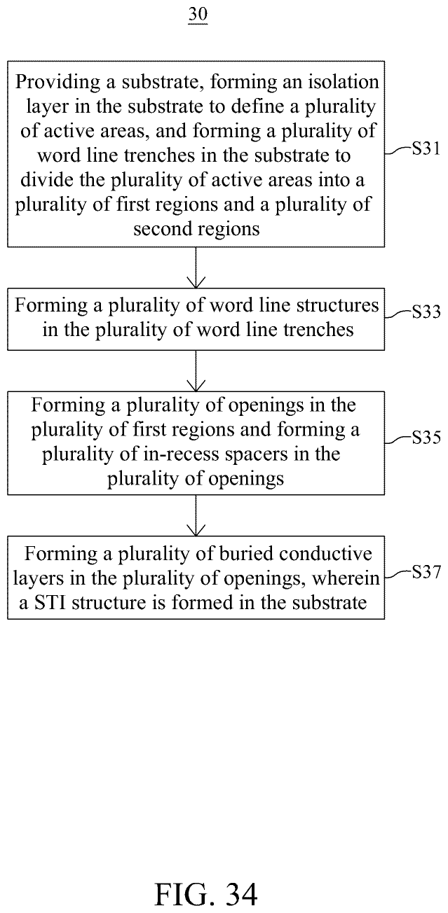

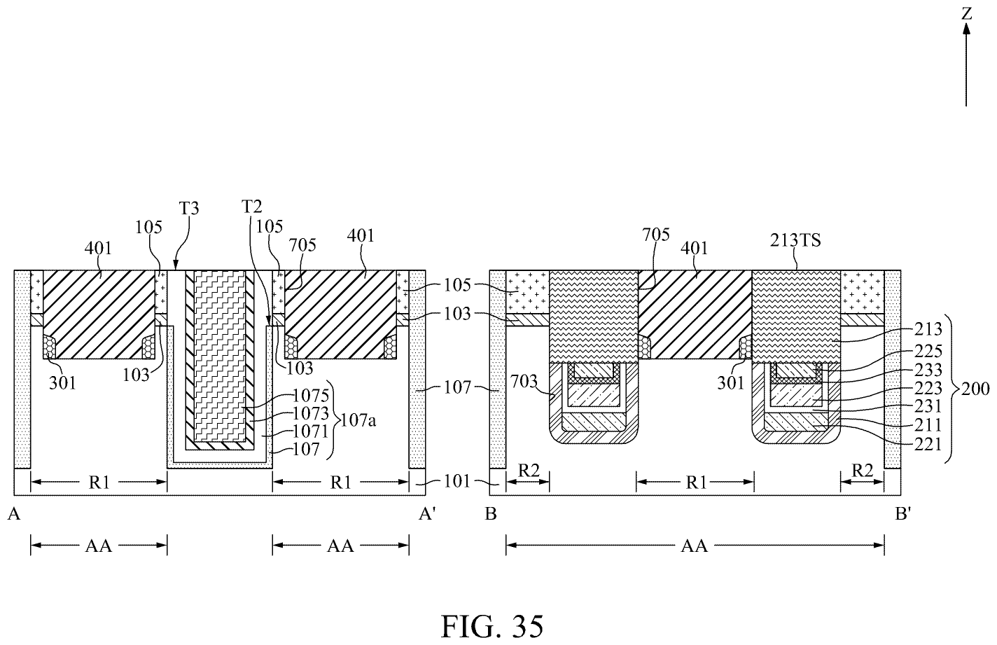

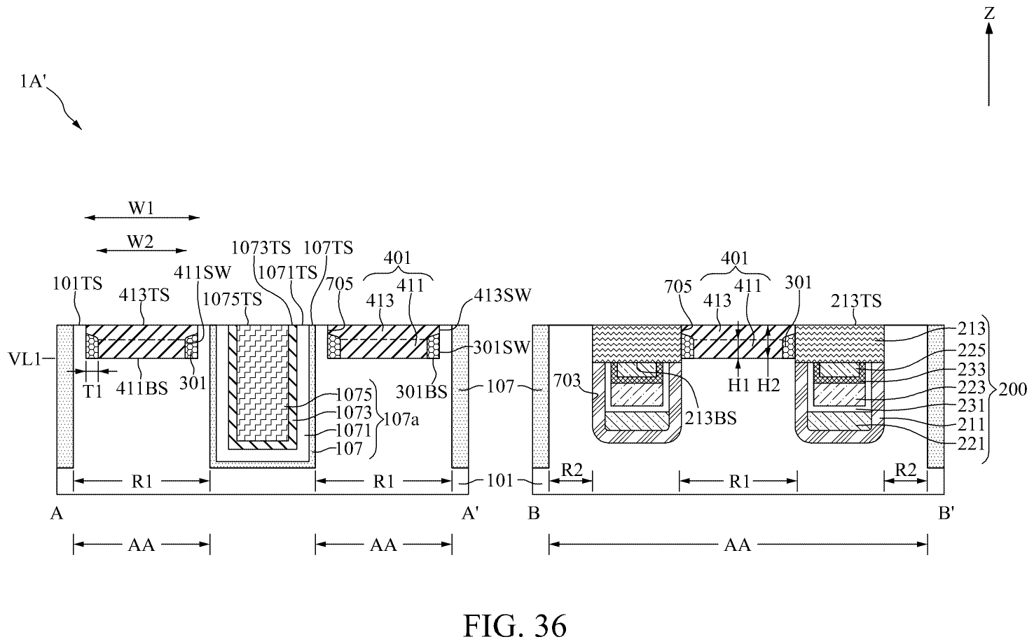

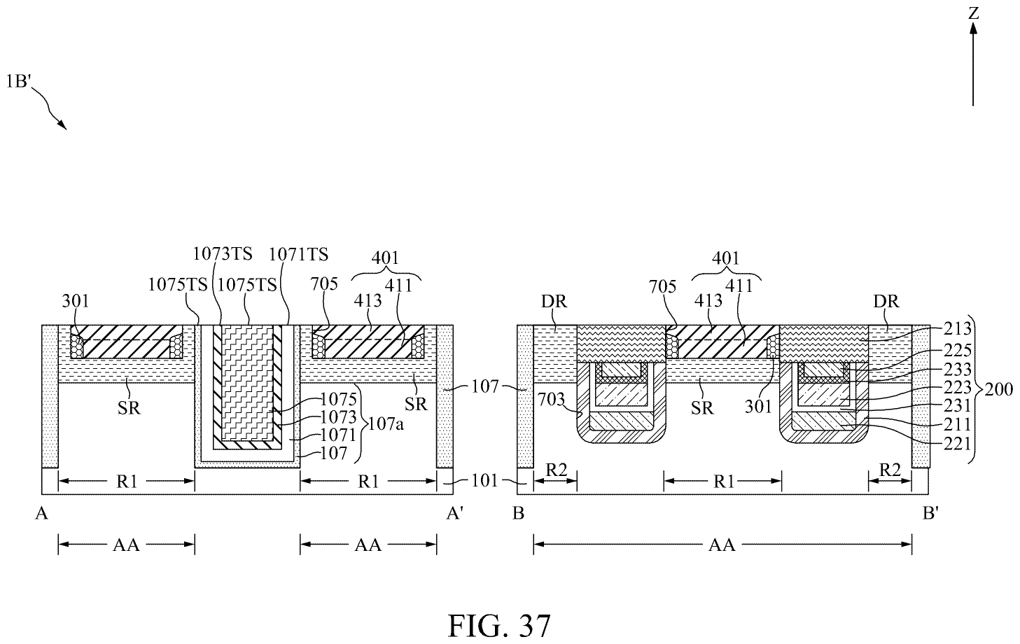

FIG. 34 is a flowchart illustrating a method for fabricating a semiconductor device in accordance with one embodiment of the present disclosure. FIGS. 35 and 36 are schematic cross-sectional diagrams taken along lines A-A′ and B-B′ in FIG. 29 illustrating part of the flow for fabricating the semiconductor device in accordance with one embodiment of the present disclosure. FIG. 37 is a schematic cross-sectional diagram taken along lines A-A′ and B-B′ in FIG. 32.

With reference to FIG. 34, the method 30 for fabricating a semiconductor device includes steps S31, S33, S35, and S37, wherein steps S31, S33, and S35 are same as steps S11, S13, and S15 of the method 10, respectively, and repeated descriptions are omitted. Step S37 of the method 30 is similar to step S17 of the method 10, wherein the difference between step S37 and step S17 is that the air gap structure 109 of step S17 is replaced by an STI (shallow trench isolation) structure 107a, which is described below.

With reference to FIGS. 34 and 35, the STI structure 107a is formed in the substrate 101. In some embodiments, the STI structure 107a is formed between two buried conductive layers 401. In some embodiments, the STI structure 107a is formed between two pad nitrides 105 and between two pad oxides 103. In some embodiments, the STI structure 107a includes a first liner 107 (i.e., same as the isolation layer 107 in FIG. 30), a second liner 1071 disposed over the first liner 107, a third liner 1073 disposed over the second liner 1071, and a trench-filling layer 1075 disposed over the third liner 1073. In some embodiments, the trench-filling layer 1075 is surrounded by the third liner 1073, the third liner 1073 is surrounded by the second liner 1071, and the second liner 1071 is separated from the substrate 101 by the first liner 107. In some embodiments, as shown in FIG. 35, a top surface T3 of the second liner 1071 is higher than a top surface T2 of the first liner 107.

In addition, the first liner 107, the second liner 1071 and the third liner 1073 of the STI structure 107a are made of different materials. For example, the first liner 107 is made of silicon oxide, the second liner 1071 is made of nitride, and the third liner 1073 is made of silicon oxynitride. Furthermore, a first etching selectivity exists between the second liner 1071 and the trench-filling layer 1075, and a second etching selectivity exists between the third liner 1073 and the trench-filling layer 1075.

With reference to FIGS. 36 and 37, a semiconductor device 1A′ of FIG. 36 is similar to the semiconductor device 1A of FIG. 31, and a semiconductor device 1B′ of FIG. 37 is similar to the semiconductor device 1B of FIG. 32, wherein the difference between the semiconductor device 1A′ and the semiconductor device 1A and the difference between the semiconductor device 1B′ and the semiconductor device 1B are in the STI structure 107a of the semiconductor devices 1A′ and 1B′. In some embodiments, as shown in FIGS. 36 and 37, after performing a planarization process, a top surface 107TS of the first liner 107, a top surface 1071TS of the second liner 1071, a top surface 1073TS of the third liner 1073 and a top surface 1075TS of the trench-filling layer 1075 are substantially coplanar.

One aspect of the present disclosure provides a semiconductor device including a substrate; a buried conductive layer including a bottom portion positioned in the substrate, and a top portion positioned in the substrate and on the bottom portion; an isolation layer positioned in the substrate; an air gap structure positioned in the isolation layer; and an in-recess spacer positioned in the substrate, surrounding the bottom portion, and covered by the top portion. A top surface of the top portion and a top surface of the substrate are substantially coplanar. A bottom surface of the in-recess spacer and a bottom surface of the bottom portion are substantially coplanar. A sidewall of the in-recess spacer and a sidewall of the top portion are substantially coplanar.

Another aspect of the present disclosure provides a semiconductor device including a substrate; a buried conductive layer including a bottom portion positioned in the substrate, and a top portion positioned in the substrate and on the bottom portion; a shallow trench isolation (STI) structure positioned in the substrate; and an in-recess spacer positioned in the substrate, surrounding the bottom portion, and covered by the top portion. A top surface of the top portion and a top surface of the substrate are substantially coplanar. A bottom surface of the in-recess spacer and a bottom surface of the bottom portion are substantially coplanar. A sidewall of the in-recess spacer and a sidewall of the top portion are substantially coplanar.

Another aspect of the present disclosure provides a method for fabricating a semiconductor device including providing a substrate and forming an isolation layer in the substrate to define a plurality of active areas; forming an opening in the substrate; conformally forming a layer of spacer material in the opening; performing a spacer etching process to remove a portion of the spacer material and form an in-recess spacer in the opening; and forming a buried conductive layer in the opening and covering the in-recess spacer, wherein an air gap structure is formed in the isolation layer.

Another aspect of the present disclosure provides a method for fabricating a semiconductor device including providing a substrate and forming an isolation layer in the substrate to define a plurality of active areas; forming an opening in the substrate; conformally forming a layer of spacer material in the opening; performing a spacer etching process to remove a portion of the spacer material and form an in-recess spacer in the opening; and forming a buried conductive layer in the opening and covering the in-recess spacer, wherein a shallow trench isolation (STI) structure is formed in the substrate.

Due to the design of the semiconductor device of the present disclosure, an electrical field near a buried conductive layer may be reduced by employing an in-recess spacer. Therefore, a gate-induced drain leakage may be reduced due to the electrical field reduction. As a result, the performance of the semiconductor device is improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a buried conductive layer comprising:
a bottom portion positioned in the substrate; and
a top portion positioned in the substrate and on the bottom portion; an isolation layer positioned in the substrate;
an air gap structure positioned in the isolation layer; and
an in-recess spacer positioned in the substrate, surrounding the bottom portion, and covered by the top portion;
wherein a top surface of the top portion and a top surface of the substrate are substantially coplanar;
wherein a bottom surface of the in-recess spacer and a bottom surface of the bottom portion are substantially coplanar;
wherein a sidewall of the in-recess spacer and a sidewall of the top portion are substantially coplanar.

2. The semiconductor device of claim 1, wherein a width ratio of a width of the bottom surface of the bottom portion to a width of the top surface of the top portion is between about 0.5 and about 0.95.

3. The semiconductor device of claim 1, wherein a ratio of a thickness of the in-recess spacer to a width of the top surface of the top portion is between about 0.025 and about 0.25.

4. The semiconductor device of claim 1, wherein a ratio of a height of the in-recess spacer to a height of the buried conductive layer is between about 0.5 and about 0.85.

5. The semiconductor device of claim 1, wherein the in-recess spacer has a square ring-shaped cross-sectional profile from a top-view perspective.

6. The semiconductor device of claim 1, wherein the buried conductive layer has a square cross-sectional profile from a top-view perspective.

7. The semiconductor device of claim 1, wherein the buried conductive layer comprises tungsten, cobalt, zirconium, tantalum, titanium, aluminum, ruthenium, copper, metal carbides, metal nitrides, transition metal aluminides, or a combination thereof.

8. The semiconductor device of claim 7, wherein the in-recess spacer comprises silicon oxide, silicon nitride, silicon oxynitride, silicon nitride oxide, boron nitride, silicon boron nitride, phosphorus boron nitride, or boron carbon silicon nitride.

9. The semiconductor device of claim 1, wherein the air gap structure includes an air gap enclosed by a liner.

10. The semiconductor device of claim 9, wherein a top surface of the air gap structure is coplanar with a top surface of the buried conductive layer.

11. A semiconductor device, comprising:
a substrate
a buried conductive layer comprising:
a bottom portion positioned in the substrate; and
a top portion positioned in the substrate and on the bottom portion;
a shallow trench isolation (STI) structure positioned in the substrate; and
an in-recess spacer positioned in the substrate, surrounding the bottom portion, and covered by the top portion;
wherein a top surface of the top portion and a top surface of the substrate are substantially coplanar;
wherein a bottom surface of the in-recess spacer and a bottom surface of the bottom portion are substantially coplanar;
wherein a sidewall of the in-recess spacer and a sidewall of the top portion are substantially coplanar.

12. The semiconductor device of claim 11, wherein the in-recess spacer has a square ring-shaped cross-sectional profile from a top-view perspective.

13. The semiconductor device of claim 11, wherein the buried conductive layer has a square cross-sectional profile from a top-view perspective.

14. The semiconductor device of claim 11, wherein the buried conductive layer comprises tungsten, cobalt, zirconium, tantalum, titanium, aluminum, ruthenium, copper, metal carbides, metal nitrides, transition metal aluminides, or a combination thereof.

15. The semiconductor device of claim 14, wherein the in-recess spacer comprises silicon oxide, silicon nitride, silicon oxynitride, silicon nitride oxide, boron nitride, silicon boron nitride, phosphorus boron nitride, or boron carbon silicon nitride.

16. The semiconductor device of claim 11, wherein the STI structure includes a first liner, a second liner disposed over the first liner, a third liner disposed over the second liner, and a trench-filling layer disposed over the third liner.

17. The semiconductor device of claim 16, wherein the trench filling layer is surrounded by the third liner, the third liner is surrounded by the second liner, and the second liner is separated from the substrate by the first liner, and a top surface of the first liner, a top surface of the second liner, a top surface of the third liner and a top surface of the trench filling layer are substantially coplanar.

18. The semiconductor device of claim 17, wherein the first liner, the second liner and the third liner of the STI structure are made of different materials, and the first liner is made of silicon oxide, the second liner is made of nitride, and the third liner is made of silicon oxynitride.

19. The semiconductor device of claim 18, wherein a first etching selectivity exists between the second liner and the trench-filling layer, and a second etching selectivity exists between the third liner and the trench-filling layer.

20. The semiconductor device of claim 11, wherein a ratio of a width of the bottom surface of the bottom portion to a width of the top surface of the top portion is between about 0.5 and about 0.95; a ratio of a thickness of the in-recess spacer to a width of the top surface of the top portion is between about 0.025 and about 0.25; and a ratio of a height of the in-recess spacer to a height of the buried conductive layer is between about 0.5 and about 0.85.
